(19) United States
(12) Patent Application Publication
(10) Pub. No.: US 2024/0092204 A1
(43) Pub. Date: Mar. 21, 2024

(54) LARGE ENERGY DISSIPATION ELECTRICAL LOAD

(71) Applicant: Fluke Corporation, Everett, WA (US)

(72) Inventor: Timothy Byron Brown, Everett, WA (US)

(21) Appl. No.: 18/471,991

(22) Filed: Sep. 21, 2023

Related U.S. Application Data
(60) Provisional application No. 63/408,743, filed on Sep. 21, 2022.

(51) Int. Cl. B60L 53/302; B60L 53/60; H05K 7/20

(52) U.S. Cl. CPC B60L 53/302; B60L 53/60; H05K 7/20327; H05K 7/20445

(57) ABSTRACT

An electrical energy absorption and heat storage system absorbs electrical energy transferred during a calibration process of an electric vehicle charging station. The system includes a resistive load, which, in operation, receives electrical energy and converts the electrical energy into heat. The heat is transferred to and stored in one or more heat storage mediums and then dissipated. The heat storage mediums may include phase-change heat storage mediums, such as water, solid heat storage mediums, such as ceramic mass (e.g., alumina), or combinations thereof. The stored heat may be dissipated as steam, contained for later dissipation, or combinations thereof. Heat sinks, convection and conduction cooling may be employed to dissipate the stored heat. An energy status of the system, together with information regarding the characteristics of the calibration process, may be used to determine whether it is appropriate to use the system to absorb the heat of the calibration process.

### BACKGROUND

### Technical Field

The present disclosure relates to calibration of electrical vehicle charging stations, and in particular, to an electrical load to dissipate a large amount of electrical energy transferred from a charging station to calibration equipment as part of the calibration process.

### Description of the Related Art

Electric vehicles are typically charged using charging stations coupled to the public power grid that dispense electricity. Commercial electric vehicle charging stations need to be calibrated to verify the metered amount of electrical energy transferred by a charging station to a vehicle is accurate.

The calibration process, which may be specified by regulations or a standard, typically requires a large amount of electrical energy to be transferred from a charging station to calibration equipment within a short period of time. For example, some standards require calibration testing at 85% of the maximum transfer current of a charging station until a specific amount of power has been transferred. Conventionally, the transferred electrical energy needs to be dissipated substantially simultaneously with the electrical energy transfers.

Currently, the transferred electrical energy is absorbed using energy absorption systems having, for example, 14KW to 24KW resistive loads and large fans. Heat generated by the resistive loads is dissipated by moving air over the resistive elements of the loads, which must happen substantially simultaneously with the electrical energy transfers. To avoid overheating of the resistive loads (and resultant damage to the resistive loads, or to vehicles storing the resistive loads): (i) limitations are placed on the maximum current used during the transfers of electrical energy; and (ii) large resistive elements and fans are employed in the energy absorption systems.

The current limitations can impact conformance to measurement standards and require long periods of time to complete calibration testing at lower current levels.

The large resistive elements and fans are bulky and heavy and can be very hot during and after use as heat continues to be released into the ambient environment by the loads. These characteristics render the energy absorption systems awkward to move from place to place. For example, such energy absorption systems can weigh up to several hundred pounds and cannot easily be picked up and moved (e.g., placed into a trunk of a car). Thus, the energy absorption systems are often towed in a trailer, requiring the use of a large vehicle to perform the calibration process. These characteristics also limit the number of absorption systems that can be easily transported and made available for use at a calibration testing site, where there might be multiple charging stations requiring calibration. This limits the ability to calibrate multiple charging stations at the same time.

### BRIEF SUMMARY

In one aspect, an electrical energy absorption and heat storage system uses resistive heating to absorb electrical energy associated with an electric vehicle charging station calibration process. The generated heat is stored in a heat storage medium of the system. The heat stored in the storage medium may then be dissipated by the system.

For example, in some embodiments, the heat generated by the resistive heating may be stored a phase-change heat storage medium, such as water, and dissipated as steam. The water will boil at around 100 degrees Celsius, limiting the temperature of the heating elements. This facilitates the use of larger transfer currents, and smaller and lighter resistive elements in the calibration system. For example, the combined weight of the resistive elements and storage medium may be as low as twenty pounds.

In some embodiments the heat generated by the resistive heating may be stored in a solid heat storage medium, such as a ceramic heat storage medium (e.g., an alumina block or mass), a metal mass (e.g., aluminum), etc., and combinations thereof, and then dissipated. For example, the heat may be stored in an alumina mass, then transferred to a phase-change heat storage medium (e.g., water or water-based medium), possibly in a controlled manner, and dissipated as steam. In another example, the solid heat storage medium may be insulated (to facilitating super-heating of the storage medium), and then subsequently cooled when convenient using conduction cooling, convention cooling, radiation cooling, or combinations thereof.

Using resistive heating to store the transferred electrical energy in a solid heat storage medium, and then dissipating the stored heat facilitates using higher transfer currents, and smaller and lighter resistive element and fan arrangements, as well as facilitating a controlled release of the stored heat instead of requiring substantially simultaneous dissipation of the heat associated with the calibration testing process.

In one aspect, an electrical energy absorption and heat storage system to absorb electrical energy transferred during a calibration process of an electric vehicle charging station includes a resistive load and a boiling reservoir. The resistive load, in operation, receives the electrical energy and converts the electrical energy into heat. The boiling reservoir, in operation, contains a phase-change heat storage medium. In operation, heat generated by the resistive load is transferred to the phase-change heat storage medium. In some embodiments, the heat transferred to the phase-change heat storage medium is released as the phase-change heat storage medium changes state. In some embodiments, the electrical energy absorption and heat storage system includes a solid heat storage medium. The resistive load is embedded in the solid heat storage medium. In operation, heat generated by the resistive load is stored in the solid heat storage medium, and selectively transferred from the solid heat storage medium to the phase-change heat storage medium.

In another aspect, an electrical energy absorption and heat storage system to absorb electrical energy transferred during a calibration process of an electric vehicle charging station includes a resistive load, a solid heat storage medium, and an insulated chamber. The resistive load is embedded in the solid heat storage medium, which is positioned in the insulated chamber. In operation, the resistive load receives the electrical energy and converts the electrical energy into heat. The heat generated by the resistive load is transferred to the solid heat storage medium, and contained by the insulated chamber. The heat may be selective dissipated at a more convenient time or place.

In another aspect, a method comprises generating one or more indications of an available energy capacity of an electrical energy absorption and heat storage system based on sensed data and stored information. One or more indications of an appropriateness of using the electric energy absorption and heat storage system to absorb electrical energy associated with an electric vehicle charging station calibration process may be generated based on the one or more indications of the available energy capacity of the electrical energy absorption and heat storage system. In some embodiments, a non-transitory computer-readable medium's contents cause a processing device to perform the method.

In another aspect, a device includes processing circuitry and an interface coupled to the processing circuitry. The processing circuitry, in operation, generates one or more indications of an available energy capacity of an electrical energy absorption and heat storage system based on sensed data and stored information. One or more indications of an appropriateness of using the electric energy absorption and heat storage system to absorb electrical energy associated with an electric vehicle charging station calibration process may be generated by the processing circuitry based on the one or more indications of the available energy capacity of the electrical energy absorption and heat storage system. The interface, in operation, outputs the one or more generated indications.

### BRIEF DESCRIPTION OF THE SEVERAL VIEWS OF THE DRAWINGS

FIG. 1 depicts an embodiment of an electrical energy absorption and heat storage system to absorb electrical energy transferred during a calibration process of an electric vehicle charging station, store the absorbed energy as heat, and dissipate the stored heat as steam.

FIG. 2 depicts embodiment of an electrical energy absorption and heat storage system to absorb electrical energy transferred during a calibration process of an electric vehicle charging station, and store the absorbed energy as heat, which facilitates controlled dissipation of the stored heat as steam.

FIG. 3 depicts an embodiment of an electrical energy absorption and heat storage system to absorb electrical energy transferred during a calibration process of an electric vehicle charging station, and store the absorbed energy as heat, which facilitates selective dissipation of the stored heat.

FIG. 4 depicts another embodiment of an electrical energy absorption and heat storage system to absorb electrical energy transferred during a calibration process of an electric vehicle charging station, and store the absorbed energy as heat, which facilitates selective dissipation of the stored heat.

FIG. 5 depicts another embodiment of an electrical energy absorption and heat storage system to absorb electrical energy transferred during a calibration process of an electric vehicle charging station, and store the absorbed energy as heat, which facilitates selective dissipation of the stored heat.

FIG. 6 is a functional block diagram of an environment in which an embodiment of an electrical energy absorption and heat storage system may be employed.

FIG. 7 is a flow diagram illustrating an embodiment of a method of generating an indication of a current energy state of an electrical load.

FIG. 8 is a flow diagram illustrating an embodiment of a method of generating an indication of the appropriateness of using an electrical load to absorb energy associated with a calibration process of an electric vehicle charging station.

FIG. 9 is a flow diagram illustrating an embodiment of a method of calculating a remaining energy capacity of an electrical load when water is employed as a phase-change heat storage medium.

FIG. 10 is a flow diagram illustrating an embodiment of a method of calculating a remaining energy capacity of an electrical load when a combination of water and a solid mass are employed as heat storage mediums.

FIG. 11 is a flow diagram illustrating an embodiment of a method of calculating a remaining energy capacity of an electrical load when a solid mass is employed as heat storage medium.

FIG. 12 is a flow diagram illustrating an embodiment of a method of evaluating the performance of an electrical load.

FIG. 13 is a flow diagram illustrating an embodiment of a method of absorbing electrical energy transferred during a calibration process of an electric vehicle charging station.

### DETAILED DESCRIPTION

The following description, along with the accompanying drawings, sets forth certain specific details in order to provide a thorough understanding of various disclosed embodiments. However, one skilled in the relevant art will recognize that the disclosed embodiments may be practiced in various combinations, with or without one or more of these specific details, or with other methods, components, devices, materials, etc. In other instances, well-known structures or components that are associated with the environment of the present disclosure, including but not limited to interfaces, ports, meters, calibrated current sources, coils, sensors, control circuits, electric vehicles, EVSEs, in an EVSE or calibration environment, have not been shown or described in order to avoid unnecessarily obscuring descriptions of the embodiments. Additionally, the various embodiments may be methods, systems, devices, etc.

Throughout the specification, claims, and drawings, the following terms take the meaning associated herein, unless the context indicates otherwise. The term “herein” refers to the specification, claims, and drawings associated with the current application. The phrases “in one embodiment,” “in another embodiment,” “in various embodiments,” “in some embodiments,” “in other embodiments,” and other variations thereof refer to one or more features, structures, functions, limitations, or characteristics of the present disclosure, and are not limited to the same or different embodiments unless the context indicates otherwise. The term “based on” is not exclusive and allows for being based on additional features, functions, aspects, or limitations not described, unless the context indicates otherwise. In addition, throughout the specification, the meaning of “a,” “an,” “one” and “the” include singular and plural references.

For the purposes of the present disclosure, unless otherwise indicated, the phrase “A and B” is nonlimiting and means one or more of (A) and one or more of (B); the phrase “A or B” is nonexclusive and means one or more of (A), one or more of (B), or one or more of (A and B); the phrase “A and/or B” means one or more of (A), one or more of (B), or one or more of (A and B); the phrase “at least one of A and B” and the phrase “one or more of A and B” both mean one or more of (A) and one or more of (B); and the phrase “at least one of A or B” and the phrase “one or more of A or B” both mean one or more of (A), one or more of (B), or one or more of (A and B). By way of extension, for example, the phrases “at least one of A, B, or C” and “one or more of A, B, or C” both mean one or more of (A), one or more of (B), one or more of (C), one or more of (A and B), one or more of (A and C), one or more of (B and C), or one or more of (A, B and C). In the above, A, B, and C represent any form or type of element, feature, arrangement, component, structure, aspect, action, step, etc.

As mentioned above, EVSEs need to be calibrated to verify the metered amount of electrical energy transferred by an EVSE is accurate. The calibration process, which may be specified by regulations or a standard, typically requires a large amount of electrical energy to be transferred from an EVSE to the calibration equipment within a short period of time. For example, some standards require calibration testing at 85% of the maximum transfer current of the EVSE until a specific amount of power has been transferred. Conventionally, the transferred electrical energy needs to be dissipated substantially simultaneously with the electrical energy transfers.

Currently, the transferred electrical energy is absorbed using energy absorption systems having, for example, 14KW to 24KW resistive loads and large fans. Heat generated by the resistive loads is dissipated by moving air over the resistive elements of the loads, which must happen substantially simultaneously with the electrical energy transfers. To avoid overheating of the resistive loads (and resultant damage to the resistive loads, or to vehicles storing the resistive loads): (i) limitations are placed on the maximum current used during the transfers of electrical energy; and (ii) large resistive elements and fans are employed in the energy absorption systems.

The current limitations can impact conformance to measurement standards and require long periods of time to complete calibration testing at lower current levels.

The large resistive elements and fans are bulky and heavy and can be very hot during and after use as heat continues to be released into the ambient environment by the loads. These characteristics render the energy absorption systems awkward to move from place to place. For example, such energy absorption systems can weigh up to several hundred pounds and cannot easily be picked up and moved (e.g., placed into a trunk of a car). Thus, the energy absorption systems are often towed in a trailer, requiring the use of a large vehicle to perform the calibration process. These characteristics also limit the number of absorption systems that can be easily transported and made available for use at a calibration testing site, where there might be multiple charging stations requiring calibration. This limits the ability to calibrate multiple charging stations at the same time.

Instead of dissipating the generated heat substantially simultaneously with the electrical energy transfers, a heat storage and dissipation device may be employed to store the heat generated by the resistive load in a heat storage medium, and dissipate the heat over time.

The heat storage medium may be a phase-change heat storage medium, such as water, which changes phase from a liquid to a gas as it absorbs heat. For example, water as a heat storage medium absorbs heat in a liquid phase until it reaches a boiling point, when the water changes state from a liquid to a gas, dissipating the stored heat as steam. Other phase-change heat storage mediums may be employed, such as materials which change from a solid state to a liquid state as heat is absorbed and released, or materials which change states multiple times in the relevant temperature ranges (e.g., from a solid state to a liquid state, and from a liquid state to a gas state).

The heat storage and dissipation device may include a storage reservoir coupled to a boiling reservoir through a feed line or tube. The storage reservoir stores the heat storage medium (e.g., water), and feeds the heat storage medium to the boiling reservoir through the feed line. The resistive load generates heat as it absorbs electrical energy associated with the calibration process. The heat is transferred to the heat storage medium and stored, and once the boiling point of the phase-change heat storage medium is reached, the stored heat is dissipated as a gas, such as steam. The water will boil at 100 degrees Celsius, limiting the temperature of the resistive load. Additional amounts of the heat storage medium may be added to the storage reservoir through an inlet as needed.

To facilitate the transfer of heat from the resistive load to the heat storage medium, and the release of steam by the heat storage and dissipation device, the resistive load may be suspended inside the boiling reservoir at an oblique angle with respect to a surface of the boiling reservoir.

This may increase the exposure area of the resistive load to the heat storage medium (e.g., as compared to positioning the resistive load on a surface of the boiling reservoir), and facilitates the release of steam, as gas bubbles are less likely to be trapped under an angled resistive load. As illustrated, walls of the boiling reservoir may be beveled or angled to facilitate the release of steam, for example, through steam vents.

The rate of steam generation and venting may be directed related to the rate of electrical energy absorbed by the resistive load. The reservoirs ideally have a combined storage capacity to store an amount of the phase-change heat storage medium (e.g., water) sufficient to allow the system to absorb the electrical energy associated with a desired electric vehicle charging station calibration process, store the heat generated by the resistive load in the phase-change storage medium, and dissipate the heat. The reservoirs, feed tube, steam vents and inlet may be sized and shaped to facilitate avoiding the buildup of pressure in the heat storage and dissipation device, and excessive noise. One or more of the reservoirs may indicate a level of the phase-change heat storage medium (e.g., water) stored in the reservoirs. For example, a gauge may indicate a level of water in a reservoir. A portion of a reservoir may be translucent, so that a water level may be visibly indicated to a user. Minimum and maximum or other level indicators (e.g., fill lines) may be employed in some embodiments.

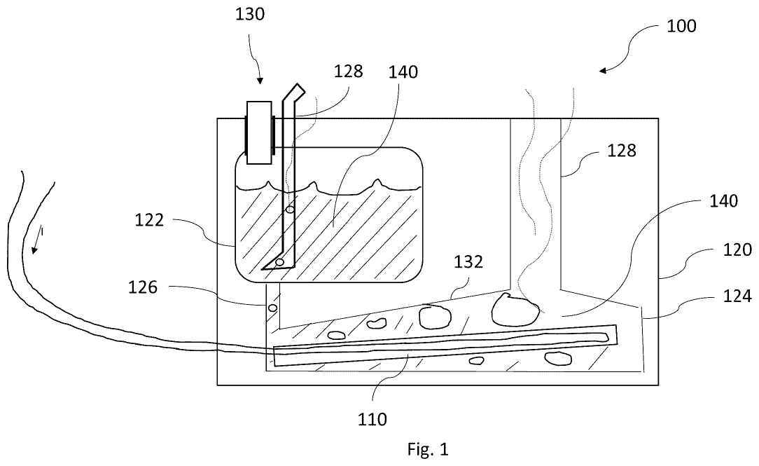

FIG. 1 depicts an embodiment of an electrical energy absorption and heat storage system 100 to absorb electrical energy transferred during a calibration process of an electric vehicle charging station. The system 100 comprises a resistive load 110 and a heat storage and dissipation device 120.

The resistive load 110, in operation, absorbs electrical energy transferred during a calibration process of an electric vehicle charging station, generating heat as a current associated with the electrical energy is conducted by the resistive load 110. The resistive load 110 may comprise, for example, one or more resistive coils (not shown) which, in operation, conduct electrical current and convert electrical energy of the electrical current into heat. The resistive load may, for example, be configured to conduct electrical currents in a range of 0 to 400 amps or more.

The heat storage and dissipation device 120, in operation, stores the heat generated by the resistive load in a heat storage medium 140, and dissipates the heat over time. The heat storage medium 140 may be a phase-change heat storage medium, such as water, which changes phase from a liquid to a gas as it absorbs heat. For example, water as a heat storage medium 140 absorbs heat in a liquid phase until it reaches a boiling point, when the water changes state from a liquid to a gas, dissipating the stored heat as steam. Other phase-change heat storage mediums may be employed, such as materials which change from a solid state to a liquid state as heat is absorbed and released, or materials which change states multiple times in the relevant temperature ranges (e.g., from a solid state to a liquid state, and from a liquid state to a gas state).

As illustrated, the heat storage and dissipation device 120 comprises a storage reservoir 122 coupled to a boiling reservoir 124 through a feed line or tube 126. The storage reservoir 122 stores the heat storage medium 140 (e.g., water), and feeds the heat storage medium 140 to the boiling reservoir 124 through the feed line 126. In operation, the resistive load 110 generates heat as it absorbs electrical energy associated with the calibration process. The heat is transferred to the heat storage medium 140 and stored, and once the boiling point of the phase-change heat storage medium is reached, the stored heat is dissipated as a gas, such as steam, through steam vents 128. The water will boil at 100 degrees Celsius, limiting the temperature of the resistive load 110. Additional amounts of the heat storage medium 140 may be added to the storage reservoir through an inlet 130.

To facilitate the transfer of heat from the resistive load 110 to the heat storage medium 140, and the release of steam by the heat storage and dissipation device 120, the resistive load 110 may be suspended inside the boiling reservoir 124 at an oblique angle with respect to a surface of the boiling reservoir 124. This may increase the exposure area of the resistive load 110 to the heat storage medium 140 (e.g., as compared to positioning the resistive load on a surface of the boiling reservoir 124), and facilitates the release of steam, as gas bubbles are less likely to be trapped under an angled resistive load. As illustrated, walls 132 of the boiling reservoir 124 may be beveled or angled to facilitate the release of steam.

In the system 100 of FIG. 1, the rate of steam generation and venting is directed related to the rate of electrical energy absorbed by the resistive load 110. The reservoirs 122, 124, ideally have a combined storage capacity to store an amount of the phase-change heat storage medium (e.g., water) sufficient to allow the system 100 to absorb the electrical energy associated with a desired electric vehicle charging station calibration process, store the heat generated by the resistive load in the phase-change storage medium 140, and dissipate the heat.

The reservoirs 122, 124, feed tube 126, steam vents 128 and inlet 130 may be sized and shaped to facilitate avoiding the buildup of pressure in the heat storage and dissipation device 120, and excessive noise. One or more of the reservoirs 122, 124 may indicate a level of the phase-change heat storage medium 140 (e.g., water) stored in the reservoirs. For example, a gauge may indicate a level of water in a reservoir 122, 124. A portion of a reservoir may be translucent, so that a water level may be visibly indicated to a user. Minimum and maximum or other level indicators (e.g., fill lines) may be employed in some embodiments.

Embodiments of the electrical energy absorption and heat storage system 100 of FIG. 1 may have more elements than illustrated, may have fewer elements than illustrated, may combine illustrated elements, may split illustrated elements into multiple elements, and may be otherwise modified in various ways. For example, the resistive load 110 may be embedded into a bottom of the boiling reservoir 124 in an embodiment, instead of being suspended at an angle in the boiling reservoir 124. In another example, the resistive load 110 may typically be electrically insulated from the phase-change heat storage medium 140. In another example, one or more of the reservoirs may be pressurized, and pressure relief valves may be employed.

The storage of the heat generated by the resistive load 110 in a phase-change heat storage medium 140, and the dissipation of the stored heat as steam, facilitates the use of larger transfer currents without overheating the resistive load 110, and reduces the risk of resultant damage to the resistive load 110. The temperature of the resistive load 110 will generally be limited by the temperature at which the phase-change material changes state (e.g., 100 degrees Celsius for water), and begins dissipating the heat.

In addition, arrangements of the resistive loads may be more compact due to the ability to transfer and store the heat in the phase-change heat storage medium, and because bulky fans are not required to cool the resistive loads. For example, the combined weight of the resistive loads 110 and the heat storage and dissipation device 120 may be as low as ten pounds in some embodiments, compared to conventional bulky systems weighing up to several hundred pounds or more. For example, the combined weight of the resistive loads and heat storage and dissipation device may typically be between 10 and 20 pounds in some embodiments. In addition, the combined volume of the resistive loads 110 and the heat storage and dissipation device 120 may be comparable to a volume of a lunch box or a cooler. For example, the combined volume of the resistive loads 110 and the heat storage and dissipation device 120 may typically be between 750 milliliters and 40 liters. In comparison, conventional bulky systems are so large and heavy that they typically must be moved around on trailers. Thus, an embodiment may have a weight and volume comparable to a lunch box or portable cooler, which may be particularly advantageous in terms of portability as compared to bulky and heavy conventional systems.

The system 100 of FIG. 1, in operation, begins to vent steam soon after beginning to absorb electrical energy, for example, as the water 140 boils to dissipate heat generated by the resistive loads 110. As noted above, the amount of steam will be directly related to the amount of electrical energy absorbed by the electrical energy absorption and heat storage system 100. It may be desirable to delay the generation of steam, or reduce or control the rate at which steam is generated. For example, it may be desired to delay the release of steam for a few minutes until a vehicle in which an electrical energy absorption and heat storage system is carried can exit a garage in which an electric vehicle charging station is located.

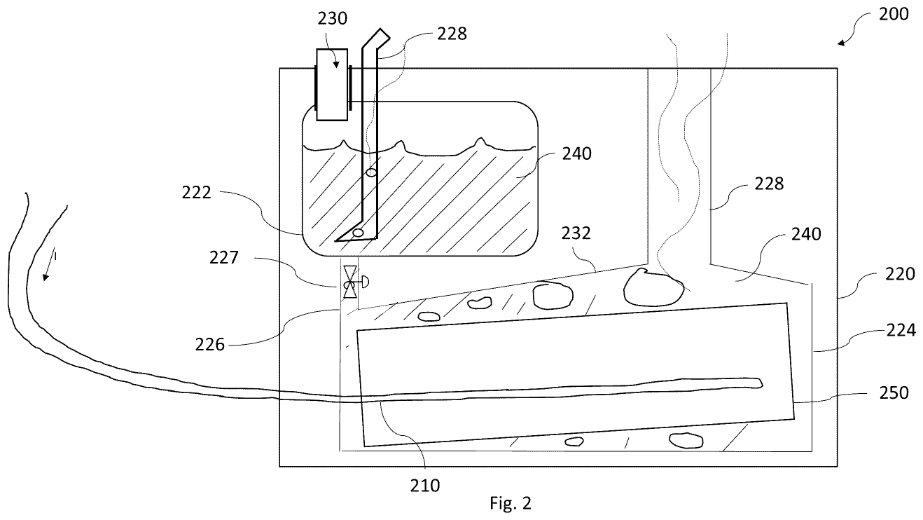

FIG. 2 depicts an embodiment of an electrical energy absorption and heat storage system 200 to absorb electrical energy transferred during a calibration process of an electric vehicle charging station, which facilitates delaying or controlling the release of gas or steam to dissipate the stored heat. The system 200 comprises a resistive load 210 and a heat storage and dissipation device 220. Similar to the resistive load 110 of FIG. 1, the resistive load 210 of FIG. 2, in operation, absorbs electrical energy transferred during a calibration process of an electric vehicle charging station, generating heat as a current associated with the electrical energy is conducted by the resistive load 210.

The heat storage and dissipation device 220 of FIG. 2, in operation, stores the heat generated by the resistive load 210 in a solid heat storage medium or thermal mass 250, for example, superheating the solid heat storage medium 250. The stored heat is then selectively transferred from the solid heat storage medium 250 to a phase-change heat storage medium 240, and dissipated as steam. The solid heat storage medium 250 may comprise, for example, a ceramic heat storage medium such as a block or mass of alumina, a metallic heat storage medium such as aluminum, etc., and various combinations thereof. The solid heat storage medium 250 may be capable of withstanding high temperatures without damaging the resistive load 210 embedded in the solid heat storage medium 250. The phase-change heat storage medium 240 may be similar to the phase-change heat storage medium 140 discussed above with reference to FIG. 1 (e.g., the phase-change heat storage medium 240 may comprise water). Other solid and phase-change heat storage mediums may be employed.

As illustrated, the heat storage and dissipation device 220 of the system 200 of FIG. 2 comprises a storage reservoir 222 coupled to a boiling reservoir 224 through a feed line or tube 226. The storage reservoir 222 stores the phase-change heat storage medium 240 and feeds the phase-change heat storage medium 240 to the boiling reservoir 224 through the feed line 226. As illustrated, the feedline 226 comprises a valve 227, which, in operation, controls a rate at which the phase-change heat storage medium 240 is transferred from the storage reservoir 222 to the boiling reservoir 224. One or more of the reservoirs 222, 224 may indicate a level of the phase-change heat storage medium 240 (e.g., water) stored in the reservoirs. For example, a gauge may indicate a level of water in a reservoir 222, 224. A portion of one or more of the reservoirs 222, 224 may be translucent, so that a water level may be visibly indicated to a user. Minimum and maximum or other level indicators (e.g., fill lines) may be employed in some embodiments.

As noted above, the resistive load 210 generates heat as it absorbs the electrical energy associated with the calibration process. The heat is initially transferred to and stored in the solid heat storage medium 250 and may be subsequently transferred from the solid heat storage medium 250 to the phase-change heat storage medium 240 for storage and dissipation. For example, the valve 227 may be closed during the absorption process when the electrical energy is converted to heat and transferred to and stored in the solid heat storage medium 250, and the valve 227 subsequently may be opened to allow the phase-change heat storage medium 240 to enter the boiling reservoir 224. In the boiling reservoir, the phase-change heat storage medium 240 contacts the solid heat storage medium 250, and heat is transfer from the solid heat storage medium 250 to the phase-change heat storage medium 240. When the phase-change heat storage medium 240 reaches a phase-change temperature, it changes its state and dissipates the stored heat. For example, the stored heat may be released as steam when the water boils, and the steam may be vented through the steam vents 228.

In some embodiments, the valve 226 may always be partially open and limit the rate at which the phase-change heat storage medium 240 enters the boiling reservoir 224. In some embodiments, the valve may be automatically controlled, for example, temperature controlled, to allow passage of the phase-change heat storage medium 240 into the boiling reservoir 224 when the temperature of the solid heat storage medium 250 reaches a threshold temperature. In some embodiments, the valve may be manually controlled. Other control mechanisms may be employed, including various combinations of control mechanisms.

To facilitate the transfer of heat from the solid heat storage medium 250 to the phase-change heat storage medium 240, and the release of steam by the heat storage and dissipation device 220, the solid heat storage medium 250 may have one or more surfaces substantially at an oblique angle with respect to a plane of a surface of the boiling reservoir 224. For example, the solid heat storage medium may be suspended inside the boiling reservoir 224 at an oblique angle with respect to a bottom surface of the boiling reservoir 224. This increases the exposure area of the solid heat storage medium 250 to the phase-change heat storage medium 240, and facilitates the release of steam, as gas bubbles are less likely to be trapped under an angled surface of the heat storage medium 250. The oblique angle may be within a range of angles. For example, a lower end of the range may be 1, 2, 3, 4, or 5 degrees, and an upper end of the range may be 89, 88, 87, 86 or 85 degrees. As illustrated, walls 232 of the boiling reservoir 224 may be beveled or angled to facilitate the release of steam from the boiling reservoir 224. The geometry of the solid heat storage medium 250 may also be optimized for contact with the phase-change heat storage medium 240 and for facilitating the release of steam upon generation.

The reservoirs 222, 224, ideally have a combined storage capacity to store an amount of the phase-change heat storage medium (e.g., water) sufficient to allow the system 200 to absorb the electrical energy associated with a desired electric vehicle charging station calibration process, store the heat generated by the resistive load, and dissipate the heat. The reservoirs 222, 224, feed tube 226, valve 227, steam vents 228 and inlet 230 may be sized, shaped and controlled to facilitate avoiding the buildup of pressure in the heat storage and dissipation device 120, and excessive noise.

Embodiments of the electrical energy absorption and heat storage system 200 of FIG. 2 may have more elements than illustrated, may have fewer elements than illustrated, may combine illustrated elements, may split illustrated elements into multiple elements, and may be otherwise modified in various ways. For example, multiple resistive loads 210 embedded in multiple solid heat storage mediums 250 may be employed and arranged inside the boiling reservoir 224 in an embodiment.

The storage of the heat generated by the resistive load 210 in heat storage mediums 250, 240 facilitates the use of larger transfer currents without overheating and damaging the resistive load 210. The temperature of the resistive load 210 will be limited due to the transfer of heat from the resistive load 210 to the solid heat storage medium 250. In addition, arrangements of the resistive loads may be more compact due to the ability to transfer and store the heat in the heat storage mediums 250, 240, and because bulky fans are not required to cool the resistive load 210.

For example, as noted above, the combined weight of the resistive loads 210 and the heat storage and dissipation device 220 may typically be between ten and twenty pounds in some embodiments, and the combined volume of the resistive loads 210 and the heat storage and dissipation device 220 may typically be between 750 milliliters and 40 liters. Thus, an embodiment may have a weight and volume comparable to a lunch box or portable cooler, which may be particularly advantageous in terms of portability as compared to bulky and heavy conventional systems.

In the system 200 of FIG. 2, the use of a combination of a solid heat storage medium 250 and a phase-change heat storage medium 240 also facilitates decoupling the rate of steam generation and venting by the heat storage and dissipation device 220 from the rate of electrical energy absorption by the resistive load 210. The solid heat storage medium 250 provides a buffer, storing heat until it is more convenient to dissipate the heat as steam, extending the period of time in which heat may be dissipated as steam (reducing the rate at which steam is generated when the dissipation process begins), or combinations thereof.

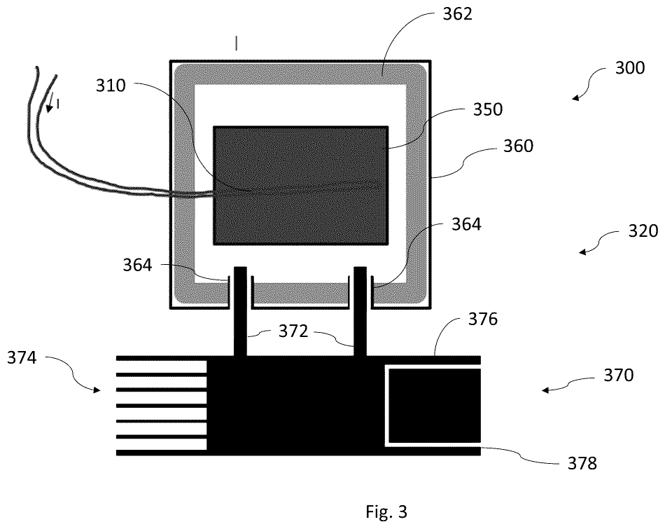

FIG. 3 depicts an embodiment of an electrical energy absorption and heat storage system 300 to absorb electrical energy transferred during a calibration process of an electric vehicle charging station, which facilitates delaying the dissipation of the stored heat, until it is more convenient or safe to dissipate the heat. The system 300 comprises a resistive load 310 and a heat storage and dissipation device 320. The resistive load 310, in operation, absorbs electrical energy transferred during a calibration process of an electric vehicle charging station, generating heat as a current associated with the electrical energy is conducted by the resistive load 310, and may be similar in some respects to the resistive load 210 described with reference to FIG. 2.

The heat storage and dissipation device 320, in operation, stores the heat generated by the resistive load 310 in a solid heat storage medium 350, for example, superheating the solid heat storage medium 350. The heat storage and dissipation device 320 comprises an insulated chamber 360 and a heat sink 370. As discussed in more detail below, the heat stored in the solid heat storage medium 350 is contained by the insulated chamber 360, and selectively transferred from the solid heat storage medium 350 to the heat sink 370. The heat sink 370 dissipates the transferred heat over time.

The solid heat storage medium 350 may be similar in some respects to the solid heat storage medium 250 of FIG. 2, and may comprise, for example, a ceramic heat storage medium such as a block or mass of alumina, a metallic heat storage medium such as aluminum, etc., and various combinations thereof. The solid heat storage medium 350 may be capable of withstanding high temperatures without damaging the resistive load 310 embedded in the solid heat storage medium 350. Other solid heat storage mediums may be employed.

As illustrated, the insulated chamber has insulating walls 362 configured to contain heat stored in the solid heat storage medium 350 until it is desired to transfer the stored heat to the heat sink 370. The insulated chamber 360 also has one or more ports or couplings 364, to provide a conductive path to remove heat from the solid heat storage medium 350 to the heat sink 370. The heat sink 370, as illustrated, comprises one or more heat conductive elements or pins 372, one or more heat dissipating fins 374, one or more heat radiation surfaces 376, and one or more convention paths 378.

The ports or couplings 364 of the insulated chamber 360 are sized and shaped to receive the heat conductive elements 372 of the heat sink 370. In operation, when it is desired to transfer the stored heat for dissipation, the heat conductive elements 372 may be inserted into the ports 364, forming a heat conductive path to conduct heat away from the solid heat storage element 350 to the heat sink 370 for dissipation. For example, the insulated chamber 360 may be placed on the pins of a heat sink 370 (e.g., stored in a vehicle, such as in the bed of a truck, not shown), or even stored at a location remote from the vehicle charging station. In another example, the pins 372 of the heat sink 370 could be inserted into the ports 364 of the insulated chamber, with the heat sink 370 positioned on top of the insulated chamber 360.

In operation, the heat dissipating fins 374 dissipate heat as gas (e.g., ambient air) circulates between the fins, the radiation surfaces 376 radiate heat, and the convention paths 378 dissipate heat as a coolant (e.g., a fluid such as water) is circulated through the convention paths 378.

Embodiments of the electrical energy absorption and heat storage system 300 of FIG. 3 may have more elements than illustrated, may have fewer elements than illustrated, may combine illustrated elements, may split illustrated elements into multiple elements, and may be otherwise modified in various ways. For example, the convection paths 378 may be omitted in some embodiments.

The storage of the heat generated by the resistive load 310 in the heat storage medium 350 and the insulated chamber 360 facilitates the use of larger transfer currents without overheating and damaging the resistive load 310. The temperature of the resistive load 310 will be limited due to the transfer of heat from the resistive load 310 to the solid heat storage medium 350. In addition, arrangements of the resistive loads may be more compact due to the ability to transfer and store the heat in the heat storage medium 350, and because bulky fans are not required to cool the resistive load 310. For example, as noted above, the combined weight of the resistive loads 310 and the solid heat storage medium 350 may typically be between ten and twenty pounds in some embodiments, and the combined volume of the resistive loads 310 and the solid heat storage medium 350 may typically be between 750 milliliters and 40 liters. Thus, an embodiment may have a weight and volume comparable to a lunch box or portable cooler, which may be particularly advantageous in terms of portability as compared to bulky and heavy conventional systems.

In the system 300 of FIG. 3, the use of a combination of a solid heat storage medium 350, an insulated chamber 360, and a heat sink 370 also facilitates decoupling the dissipation of heat by the heat storage and dissipation device 320 from the rate of electrical energy absorption by the resistive load 310. The solid heat storage medium 350 and the insulated chamber 360 provide a buffer, storing heat until it is more convenient or safer to dissipate the heat using the heat sink 370, extending the period of time in which heat may be dissipated, and allowing for more convenient storage of the heat sink 370, such as at location remote from an electric vehicle charging station being calibrated.

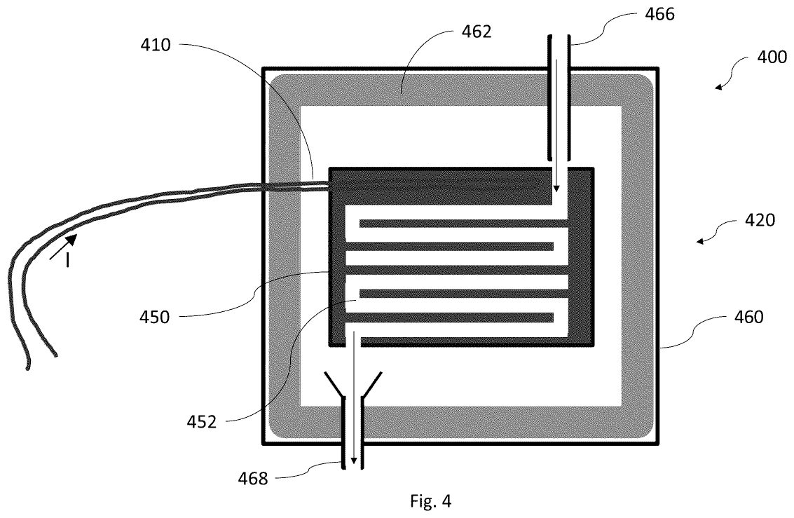

FIG. 4 depicts an embodiment of an electrical energy absorption and heat storage system 400 to absorb electrical energy transferred during a calibration process of an electric vehicle charging station, which facilitates delaying the dissipation of the stored heat. The system 400 comprises a resistive load 410 and a heat storage and dissipation device 420. The resistive load 410, in operation, absorbs electrical energy transferred during a calibration process of an electric vehicle charging station, generating heat as a current associated with the electrical energy is conducted by the resistive load 410, and may be similar in some respects to the resistive load 310 described with reference to FIG. 3.

The heat storage and dissipation device 420, in operation, stores the heat generated by the resistive load 410 in a solid heat storage medium 450, for example, superheating the solid heat storage medium 450. The heat storage and dissipation device 420 comprises an insulated chamber 460. As discussed in more detail below, the heat stored in the solid heat storage medium 450 is contained by the insulated chamber 460, and selectively removed from the solid heat storage medium 450 by circulating a gas or liquid cooling media through a convention path 452 in the solid heat storage medium 450.

The solid heat storage medium 450 may comprise, for example, a ceramic heat storage medium such as a block or mass of alumina, a metallic heat storage medium such as aluminum, etc., and various combinations thereof. The solid heat storage medium 450 has one or more convection paths 452 to facilitate removal of heat from the solid heat storage medium 450 to a gas (e.g., air) or liquid (e.g., water) cooling media circulating through the one or more convection paths 452. The solid heat storage medium 450 may be capable of withstanding high temperatures without damaging the resistive load 410 embedded in the solid heat storage medium 450. Other solid heat storage mediums may be employed.

As illustrated, the insulated chamber 460 has insulating walls 462 configured to contain heat stored in the solid heat storage medium 450 until it is desired to remove the stored heat. The insulated chamber 460 also has one or more inlet ports or couplings 466 and one or more outlet ports or couplings 468 to provide a path for the gas or liquid medium to circulate through the conduction path 452 to remove heat from the solid heat storage medium 450 to the circulating cooling media.

In operation, when it is desired to remove the stored heat from the solid heat storage medium 450, the cooling media may be circulated through the heat conductive path 452 via the input ports 466 and output ports 468, with the stored heat being transferred to the cooling media and remove from the insulated chamber 460.

Embodiments of the electrical energy absorption and heat storage system 400 of FIG. 4 may have more elements than illustrated, may have fewer elements than illustrated, may combine illustrated elements, may split illustrated elements into multiple elements, and may be otherwise modified in various ways. For example, the insulated chamber 460 may be modified to include ports or couplings sized and shaped to receive conductive elements of a heat sink (see ports 364 of the insulated chamber 360 of FIG. 3, which are sized and shaped to receive heat conductive elements 372 of a heat sink 370), in addition to having input and output ports 466, 468 to facilitate the circulation of coolant through the convection path 452.

The storage of the heat generated by the resistive load 410 in heat storage medium 450 and the insulated chamber 460 facilitates the use of larger transfer currents without overheating and damaging the resistive load 410. The temperature of the resistive load 410 will be limited due to the transfer of heat from the resistive load 410 to the solid heat storage medium 450. In addition, arrangements of the resistive loads may be more compact due to the ability to transfer and store the heat in the heat storage mediums 450, and because bulky fans are not required to cool the resistive load 410. For example, the combined weight of the resistive loads 410 and the heat storage and dissipation device 420 may be as low as twenty pounds in some embodiments, compared to conventional bulky systems weighing up to several hundred pounds.

In the system 400 of FIG. 4, the use of a combination of a solid heat storage medium 450, an insulated chamber 360, and a conduction path 452 through which a cooling media may be circulated also facilitates decoupling the dissipation of heat by the heat storage and dissipation device 420 from the rate of electrical energy absorption by the resistive load 410. The solid heat storage medium 450 and the insulated chamber 460 provide a buffer, storing heat until it is more convenient or safer to dissipate the heat by circulating a cooling media through the convection path 452.

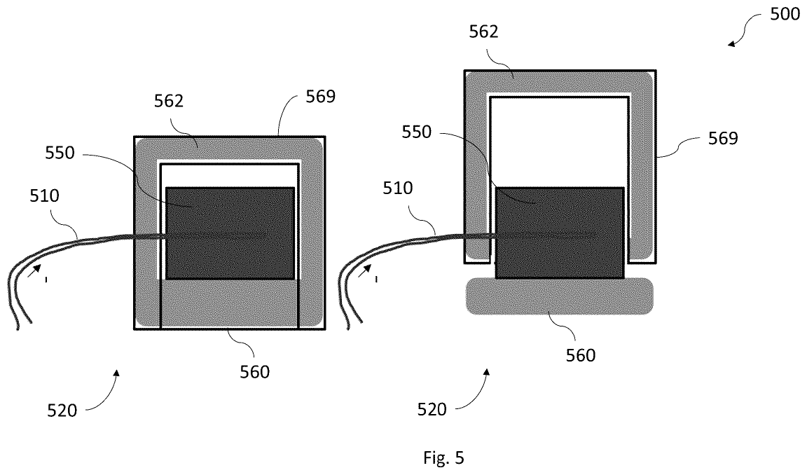

FIG. 5 depicts an embodiment of an electrical energy absorption and heat storage system 500 to absorb electrical energy transferred during a calibration process of an electric vehicle charging station, which facilitates delaying the dissipation of the stored heat. The system 500 comprises a resistive load 510 and a heat storage and dissipation device 520. The resistive load 510, in operation, absorbs electrical energy transferred during a calibration process of an electric vehicle charging station, generating heat as a current associated with the electrical energy is conducted by the resistive load 510, and may be similar in some respects to the resistive load 310 described with reference to FIG. 3.

The heat storage and dissipation device 520, in operation, stores the heat generated by the resistive load 510 in a solid heat storage medium 550, for example, superheating the solid heat storage medium 550. The heat storage and dissipation device 520 comprises an insulated chamber 560. As discussed in more detail below, the heat stored in the solid heat storage medium 550 is contained by the insulated chamber 560, and selectively dissipated by removing or opening a portion 569 of the insulated chamber 560.

The solid heat storage medium 550 may comprise, for example, a ceramic heat storage medium such as a block or mass of alumina, a metallic heat storage medium such as aluminum, etc., and various combinations thereof, and may be similar in some respect to the solid heat storage medium 350 of FIG. 3 or to the solid heat storage medium 450 of FIG. 4.

As illustrated, the insulated chamber 560 has insulating walls 562 configured to contain heat stored in the solid heat storage medium 550 until it is desired to remove the stored heat. The insulated chamber 560 also has one or more removable or openable portions 569 to facilitate dissipation of stored heat through convection (e.g., exposure to ambient air), or other means, such as by using a heat sink (see heat sink 370 of FIG. 3), a cooling media, etc. In operation, when it is desired to contain the heat, the removable portion 569 is positioned or closed to contain the heat in the insulated chamber 560, as illustrated on the left side of FIG. 5. When it is desired to dissipate the heat, the removeable portion 569 is removed or opened, to facilitate dissipation of the stored heat, as illustrated on the right side of FIG. 5. For example, it may be desired to contain the heat at the calibration site, and release or dissipate the heat later at another location.

Embodiments of the electrical energy absorption and heat storage system 500 of FIG. 5 may have more elements than illustrated, may have fewer elements than illustrated, may combine illustrated elements, may split illustrated elements into multiple elements, and may be otherwise modified in various ways. For example, the insulated chamber 560 may be modified to include ports or couplings sized and shaped to receive conductive elements of a heat sink (see ports 364 of the insulated chamber 360 of FIG. 3, which are sized and shaped to receive heat conductive elements 372 of a heat sink 370), to include a conductive path, or input and output ports, to facilitate circulation of a cooling media through the solid heat storage medium 550 (see conductive path 552 and input and output ports 466, 468 of FIG. 4), etc., or various combinations thereof.

The storage of the heat generated by the resistive load 510 in heat storage medium 550 and the insulated chamber 560 facilitates the use of larger transfer currents without overheating and damaging the resistive load 510. The temperature of the resistive load 510 will be limited due to the transfer of heat from the resistive load 510 to the solid heat storage medium 550, as well as by the removal of heat from the solid heat storage medium 550 through the removal or opening of removable or openable portion 569. In addition, arrangements of the resistive loads may be more compact due to the ability to transfer and store the heat in the heat storage mediums 550, and because bulky fans are not required to cool the resistive load 510. For example, the combined weight of the resistive loads 510 and the heat storage and dissipation device 520 may be as low as twenty pounds in some embodiments, compared to conventional bulky systems weighing up to several hundred pounds.

In the system 500 of FIG. 5, the use of a combination of a solid heat storage medium 550, an insulated chamber 560 having a removeable or openable portion also facilitates decoupling the dissipation of heat by the heat storage and dissipation device 520 from the rate of electrical energy absorption by the resistive load 510. The solid heat storage medium 550 and the insulated chamber 560 provide a buffer, storing heat until it is more convenient or safer to dissipate the heat by removing or opening the removeable or openable portion 569.

The available heat storing capacity of embodiments of an electrical energy absorption and heat storage system, such as the systems described above with reference to FIGS. 1 to 5, may not always be sufficient to permit absorption of the electrical energy transferred during a calibration process of an electric vehicle charging station in a convenient or safe manner. In addition to raising safety concerns, attempting to transfer electrical energy to an electrical energy absorption and heat storage system larger than the current energy absorption capacity of the system may cause damage to the system or to the environment in which the system operates.

The available capacity may depend on a number of factors. For example, with reference to the system 100 of FIG. 1 or the system 200 or FIG. 2, whether there is sufficient amount of a phase-change heat storage medium (water) available to absorb and dissipate the heat associated with a calibration process would need to be considered. In another example, with reference to systems 100 to 500 of FIGS. 1 to 5 described above, a current temperature of the heat storage medium(s) employed may need to be considered.

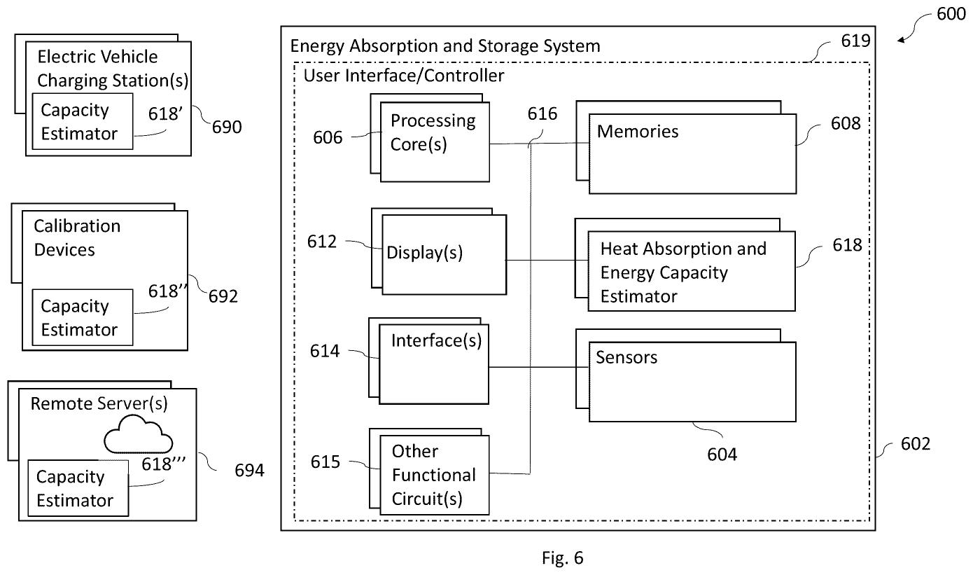

FIG. 6 is a functional block diagram of an embodiment of an environment 600 in which one or more electrical energy absorption and heat storage systems 602 may be employed. The environment 600 as illustrated also includes one or more electric vehicle charging stations 690, one or more calibration devices 692, and one or more remote servers 694, which may be cloud servers. In operation, a calibration device 692 may send electrical energy associated with a calibration process applied to an electric vehicle charging station 690 to an energy absorption and storage system 602, where the electrical energy may be converted to heat. The heat may be stored and then dissipated by the energy absorption and storage system 602, for example, as discussed above with reference to FIGS. 1-5.

To avoid unsafe handling of the energy associated with a calibration process, the one or more electrical energy absorption and heat storage systems 602, in operation, may include circuitry to monitor one or more indications of a state of the respective system (e.g., an indication of a current amount of heat energy stored in the system), and may provide one or more indications of a capacity of the respective electrical energy absorption and heat storage systems 602 to absorb the electrical energy associated with a calibration process based on the monitored indications. The indications of the capacity of the system 602 to absorb electrical energy may be indirect (e.g., an indication of the amount of heat currently stored in the system; an indication of an available heat storage capacity;

etc.) or direct (e.g., an estimate of the available energy storage capacity determined based on the monitored indications). The structures of the energy absorption energy absorption and heat storage systems 602 of FIG. 6 may otherwise be similar to one or more of the structures of the energy absorption and heat storage systems 100, 200, 300, 400, 500 described above with reference to FIGS. 1 to 5.

As illustrated, the energy absorption and heat storage systems 602 of FIG. 6 each include one or more sensors 604, such as one or more temperature sensors, one or more pressure sensors, one or more motion sensors, one or more position sensors, one or more quantity sensors, etc. The one or more sensors 604, in operation, may generate audio, visual or electrical signals or displays indicative of a capacity of the respective energy absorption and heat storage system 602 to store heat, and thus provide an indication of whether the respective system 602 may be conveniently and safely employed to absorb the electrical energy associated with an electric vehicle charging station calibration process.

For example, a thermometer 604 may display a temperature of the heat storage medium of the system 602, and the temperature may be used to determine whether there is sufficient heat storage capacity remaining in the system 602 for a particular calibration process. In another example, a temperature sensor 604, in operation, may generate digital or analog signals based on an ambient temperature, heat storage medium temperatures, temperature differences, etc., and various combinations thereof. The temperature sensor 604 may typically comprise a resistance temperature detector, a semiconductor detector, a junction detector, etc., which converts an indication of a temperature or a temperature change into electrical signals.

Determining whether an energy absorption and heat storage system 602 has sufficient heat storage capacity remaining to be safely and conveniently used to absorb the electrical energy of a particular calibration process based on a temperature reading, such as a temperature of a heat storage medium, may be difficult to do quickly in the field by a person performing a calibration operation, may not be sufficiently accurate for some applications, and may not take other factors into consideration, such as performance degradation over time. One or more embodiments may provide for more robust indications of whether an energy absorption and heat storage system 602 has sufficient heat storage capacity remaining to be safely and conveniently used to absorb the electrical energy associated with a particular calibration process.

As illustrated, in addition to the one or more sensors 604, the energy absorption and heat storage systems 602 also comprise one or more processing cores 606, one or more memories 608, one or more displays 612, one or more interfaces 614, one or more other functional circuits 615, one or more bus systems 616, one or more heat absorption and energy capacity estimators 618 and a user interface or controller 619.

The processing cores 606 may comprise, for example, one or more processors, a state machine, a microprocessor, a programmable logic circuit, discrete circuitry, logic gates, registers, etc., and various combinations thereof. The processing cores 606 may control overall operation of the system 602, execution of application programs by the system 602 (e.g., programs which may use sensor data, stored or received information, or various combinations thereof, to perform various functions, such as generating an indication of a capacity of the system 602 to absorb electrical energy), etc.

The one or more memories 608 may include one or more volatile and/or non-volatile memories (e.g., registers, memory arrays), which may store, for example, all or part of instructions and data related to control of the system 602, applications and operations performed by the system 602, etc. For example, programs, identification information (e.g., a serial number, model type, etc.) and usage information (e.g., energy absorption and temperature change information) may be stored in the one or more memories 608, and used by an application executing on the one or more processing cores 606 to generate an indication of a current energy absorption capacity of the system 602.

The one or more displays 612 may display information pertaining to a current energy absorption capacity of the system 602. For example, current temperature information may be displayed, a binary indication may be displayed (e.g., an indication the system is ready or not ready to absorb a quantity of electrical energy), etc. The one or more interfaces 614 (e.g., wireless communication interfaces, wired communication interfaces, etc.) may couple the system to other components of the environment, such as to a calibration device 692, a remote server 694, another system 602, etc. The one or more other functional circuits 615 may include antennas, power supplies, one or more built-in self-test (BIST) circuits, etc. The main bus system 616 may include one or more data, address, power and/or control buses coupled to the various components of the system 602.

The system 602 also includes a heat absorption and energy capacity estimator or circuit 618, which, in operation, generates one or more indications of a current capacity of the system 602 to absorb electrical energy, such as electrical energy associated with a calibration process, based on sensor data, stored data, received data, or various combinations of data, for example, as discussed in more detail below.

The user interface or controller 619 may, in operation, receive user commands, such as a command to generate an indication of a current electrical energy absorption capacity of the system 602, and may receive responses to such commands. The user interface or controller 619 may be physically integrated into a body or other component of the system 602 (e.g., into the heat storage and dissipation device 120 of FIG. 1, the insulated chamber 360 or heat sink 370 of FIG. 3, etc.), or may be a separate device which may be handheld and communicatively coupled to other components of the system 602. The user interface or controller 619 may include all or part of the sensors 604, processing cores 606, memories 608, displays 612, interfaces 614, other functional circuits 615, bus system 616 and heat absorption and energy capacity estimator 618. For example, a body of the system 602 may include one or more sensors 604 and a wired or wireless interface may be coupled to the sensors 604 to convey sensor data to the user interface 619, with the user interface 619 possibly including other sensors, the processing cores 606, the memories 608, the displays 612, other interfaces 614, other functional circuits 615, bus system 616 and heat absorption and energy capacity estimator 618.

In addition, the capacity estimator 618 may be implemented in a distributed manner. For example, all or part of the functionality of the capacity estimator may be performed by the capacity estimator 618 of an energy absorption and heat storage system 602, by a capacity estimator 618′ of an electric vehicle charging station 690, by a capacity estimator 618″ of a calibration device 692, by a capacity estimator 618′″ of a remote or cloud server 694, etc., and various combinations thereof. The electric vehicle charging stations 690, calibration devices 692 and remote servers 694 may comprise circuitry to implement the capacity estimators 618′, 618″, 618′″, such as processors and memory, etc. (not shown).

For example, a body of the system 602 may include one or more sensors 604 and a wired or wireless interface may be coupled to the sensors 604 to convey sensor data to the user interface 619. The user interface 619 may forward the sensor data and other data to a capacity estimator 618″ of a calibration device 692 or to a capacity estimator 618′″ of a remote server, for a determination of the capacity of the system 602 to absorb the energy associated with a calibration process. The determination may be returned to the user interface 619 and displayed on a display 612 for a user. The user may decide whether to use the system 602 to absorb energy associated with the calibration process based on the displayed determination.

Calibration information may be exchanged between electrical energy absorption and heat storage systems 602, the calibration devices 692, the electric vehicle charging stations 690 and the remote servers 694, for various purposes. For example, a calibration device 692 may query an electrical charging station 690 for calibration information, such as a type and configuration of the charging station 690. The calibration device 692 may forward the calibration information or a query generated based on the calibration information to a remove server 694 and may receive calibration process instructions from the remove server 694 in response. The calibration device 692 may then query an energy absorption and heat capacity storage system 602 to determine whether the system 602 has sufficient capacity to store energy associated with a calibration process consistent with the calibration instructions. For example, the calibration device 692 may request the system 602 to provide sensed data related to a current energy state of the system 602, such as sensed temperature and pressure data.

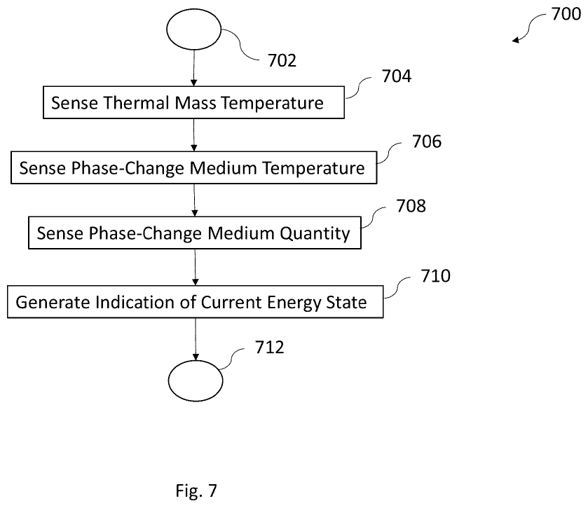

FIG. 7 illustrates an embodiment of a method 700 of generating an indication of a current energy state of an electrical load that may be used to absorb the electrical energy associated with an electric vehicle charging station calibration process, such as a current energy state of an energy absorption and heat storage system 602 of FIG. 6. For convenience, FIG. 7 will be described with reference to the system 200 of FIG. 2 and the environment 600 of FIG. 6. The method 700 may be performed, for example, using or under the control of an energy capacity estimator, such as one or more of the energy capacity estimators 618, 618′, 618″, 618′″ of FIG. 6.

The method 700 starts at 702, for example, in response to a request from a user interface 619 or a calibration device 692 for an indication of the current energy state of the system 200 or the system 602. The method 700 proceeds from 702 to 704.

At 704, the method 700 senses one or more temperatures of a thermal mass, such as the solid heat storage medium 250 of FIG. 2. This may be performed, for example, using one or more thermometers or other thermal or temperature sensors. The method 700 proceeds from 704 to 706.

At 706, the method 700 senses one or more temperatures of a phase-change heat storage medium, such as the phase-change heat storage medium 240 of FIG. 2, for example, using one or more thermometers or other thermal or temperature sensors. With reference to FIG. 2, a temperature of the phase-change heat storage medium 240 in the storage reservoir 222 and a temperature of the phase-change heat storage medium 240 in the boiling reservoir 224 may be sensed. The method 700 proceeds from 706 to 708.

At 708, the method 700 senses one or more quantities of a phase-change heat storage medium, such as the phase-change heat storage medium 240 of FIG. 2, for example, using one or more gauges or other quantity sensors. With reference to FIG. 2, a quantity of the phase-change heat storage medium 240 in the storage reservoir 222 and a quantity of the phase-change heat storage medium 240 in the boiling reservoir 224 may be sensed. The method 700 proceeds from 708 to 710.

At 710, the method 700 generates, based on the sensed data, one or more indications of a current energy state of an electrical load, such as a current energy state of the energy absorption and heat storage system 200 of FIG. 2 or of an energy absorption and heat storage system 602 of FIG. 6. For example, temperature and quantity gauges may display the sensed temperatures and quantities. In another example, one or more signals may be generated which are indicative of the sensed quantities. The method 700 proceeds from 710 to 712.

At 712, the method 700 may stop, may provide the one or more generated indications of a current energy state of the electric load to one or more calling processes or applications, such as an energy capacity estimation process executing on an energy capacitor estimator, may perform other operations, such as initiating a heat dissipation operation based on an indicated current energy state, etc.

Embodiments of the method 700 of FIG. 7 may contain additional acts not shown in FIG. 7, may not contain all of the acts shown in FIG. 7, may perform acts shown in FIG. 7 in various orders, may combine acts, may split acts into separate acts, and may be otherwise modified in various respects. For example, FIG. 7 may be modified to perform acts 704, 706 and 708 in parallel in some embodiments, to omit acts 706 and 708 in some embodiments, to obtain additional sensed data, such as sensing an ambient temperature or pressure, to provide an audio or visual indication of the current energy state of the electrical load, etc., and various combinations thereof.

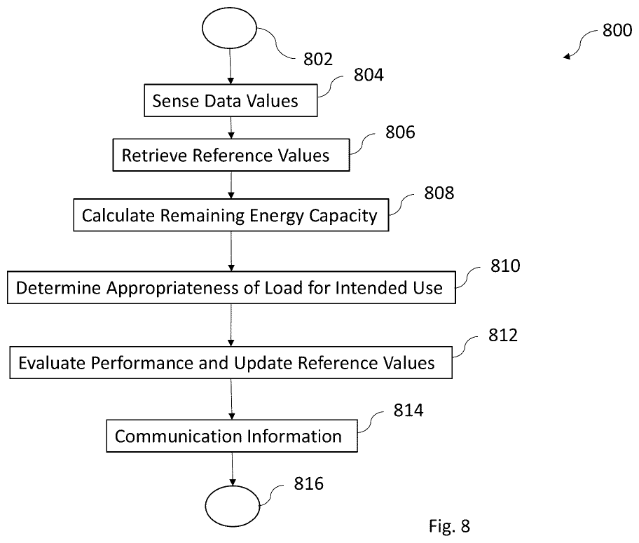

FIG. 8 illustrates an embodiment of a method 800 of generating an indication of the appropriateness of using an electrical load to absorb the electrical energy associated with an electric vehicle charging station calibration process, such as an indication of whether it is appropriate to use a particular energy absorption and heat storage system 602 of FIG. 6 to absorb electrical energy associated with applying a particular calibration process to a particular electrical vehicle charging station 690. For convenience, FIG. 8 will be described with reference to the systems 100, 200, 300, 400, 500 of FIGS. 1-5 and the environment 600 of FIG. 6. The method 800 may be performed, for example, using or under the control of an energy capacity estimator, such as one or more of the energy capacity estimators 618, 618′, 618″, 618″' of FIG. 6.

The method 800 starts at 802, for example, in response to a request from a user interface 619 or a calibration device 692 for an indication of whether it is appropriate to employ a particular energy absorption and heat storage system 602 to absorb electrical energy associated with a particular charging station calibration process. The method 800 proceeds from 802 to 804.

At 804, the method 800 senses or retrieves stored data associated with the determination of whether it is appropriate to use a particular energy absorption and heat storage system to absorb electrical energy associated with a particular charging station calibration process. The data may be sensed using one or more of sensors, such as the sensors 604 of FIG. 6. The sensed or stored data may include, for example, an ambient temperature, such as an ambient temperature of the environment 600, an ambient pressure, such as an ambient pressure of the environment 600, a temperature of a heat storage medium, such as a temperature of a phase-change heat storage medium 140, 240 of FIGS. 1 and 2, or of a solid heat storage medium of mass 250, 350, 450, 550 of FIGS. 2 through 5, an amount of a phase-change heat storage medium available, etc., and various combinations thereof. The method 800 proceeds from 804 to 806.

At 806, the method 800 retrieves reference values associated with the determination of whether it is appropriate to use a particular energy absorption and heat storage system to absorb electrical energy associated with a particular charging station calibration process. The reference values may stored in one or more memories, such as a memory 608 of an energy absorption and heat storage device 602, a memory of an electric vehicle charging station 690, a memory of a calibration device 692, a memory of a user interface 619, a memory of a remote or cloud server 694, etc., or various combinations thereof. Look-up tables may be employed in some embodiments to retrieve reference values. For example, a memory 608 of an energy absorption and heat storage system 602 may store an identifier of the energy absorption and heat storage system 602, and the identifier may be used to retrieve reference values stored in a memory of a calibration device 692 or of a remote server 694. Serial numbers or QR codes (e.g., a bar code on an external surface of an energy absorption and heat storage device 602) may be employed in some embodiments and scanned to facilitate retrieval of reference values.

The reference values may include, for example, a mass of a thermal mass that is used to store heat, such as a mass of a solid heat storage medium 250, 350, 450, 550 of FIGS. 2 through 5; a heat capacity of a thermal mass; a maximum mass of a phase-change heat storage medium, such as water (e.g., a capacity of a reservoir 122, 124, 222, 224 of FIGS. 1 and 2); a minimum mass of a phase-change heat storage medium (e.g., for safety purposes); a minimum and maximum flow rate of a phase-change heat storage medium through a valve, such as the valve 227 of FIG. 2; conversion information (e.g., look-up tables) to convert from sensed information to mass (e.g., to convert sensed water levels to mass); information regarding a relationship of boiling point to sensed values (e.g., temperature, pressure, etc.); maximum design temperatures of thermal masses; resistance of electrical resistive elements (e.g., resistance of resistive loads 110, 210, 310, 410, 510 of FIGS. 1 through 5); historical performance information (e.g., sensed temperature changes in response to known loads under various operating conditions); alarm set points, such as for water levels, temperatures, changes in performance values, control thresholds; etc.; and various combinations thereof. The retrieved reference values also may include information regarding a particular calibration process to be performed, such as an identification of a calibration process to be employed, rates and durations of energy transfers associated with a calibration process, information regarding an electric vehicle charging station to be calibrated, information regarding a calibration device to be employed, etc., and various combinations thereof. The method 800 proceeds from 806 to 808.

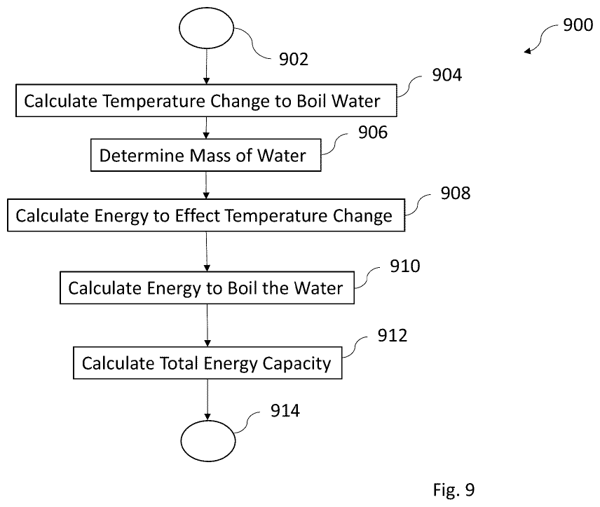

At 808, the method 800 generates or calculates one or more indications of a remaining energy capacity of an energy absorption and heat storage device, such as an energy absorption and heat storage device 602 of FIG. 6, based on the sensed data values and the retrieved reference values. Calculating a remaining energy capacity of an energy absorption and heat storage device may include determining a current energy state of the energy absorption and heat storage device, for example as described above with reference to FIG. 7. Examples of calculating a remaining energy capacity are discussed below with reference to FIGS. 9 through 11. The method 800 proceeds from 808 to 810.

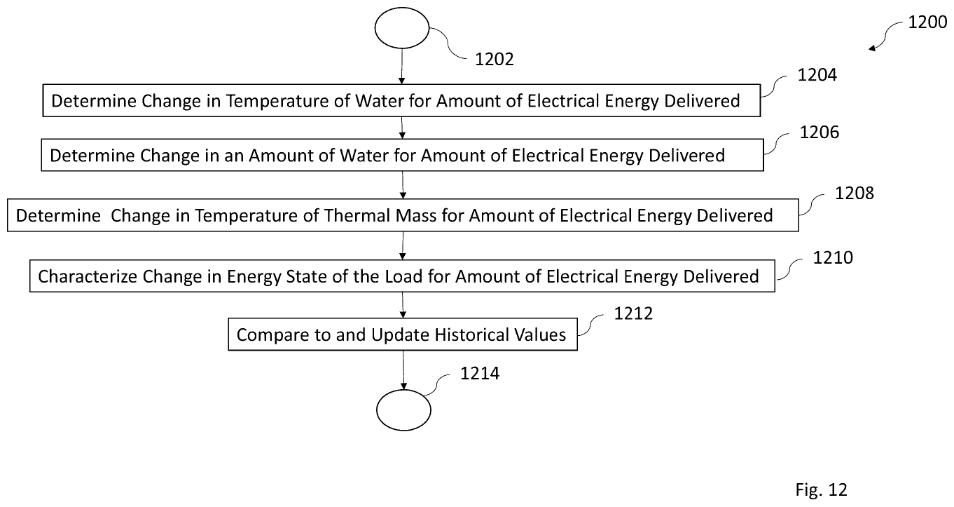

At 810, the method 800 determines or generates one or more indications of an appropriateness of a load, such as an energy absorption and heat storage device 602, for an intended use in a calibration process based on the calculated remaining energy capacity of the load, and the retrieved information regarding a particular calibration process to be performed. An example embodiment of determining the appropriateness of a load for use in a particular calibration process is discussed below with reference to FIG. 12. The method 800 proceeds from 810 to 812.

At 812, the method 800 evaluates the performance of the electrical load during the absorption of electrical energy associated with a calibration process. With reference to the systems 100, 200, 300, 400, 500 of FIGS. 1 through 5, the evaluation may include, for example, calculating a change in temperature of a phase-change heat storage medium 140, 240 of FIGS. 1 and 2, such as water, for an amount of electrical energy absorbed, calculating a change in the amount of water for an amount of electrical energy absorbed, calculating a change in temperature of a thermal mass, such as a solid heat storage medium 250, 350, 450, 550 of FIGS. 1 and 2, such as a mass of alumina, etc., and various combinations thereof. The calculated information may be used to characterize the change in energy of the electrical load compared to the amount of electrical power absorbed. Comparisons to stored historical performance evaluations may be used to detect changes in performance, such as a degradation in performance, and updated information may be stored for use in current or future calculations of the remaining energy capacity of the load at 808, determinations of the appropriateness of using the electrical load at 810, etc. For example, changes in performance might indicate oxidation of the resistive load or a crack in the insulation material, in which case maintenance (e.g., demineralization of the resistive load 110 or of the boiling reservoir 124, 224) or repair (e.g., of the insulating walls 362, 462, 562) may be scheduled. The method 800 proceeds from 812 to 814.

At 814, the method 800 communicates information regarding the electrical load or the calibration process to or from another device or to or from a user. For example, information regarding the electrical load may be communicated to or from a calibration device, such as a calibration device 692 of FIG. 6, to or from a remote or cloud server, such as a remote server 694 of FIG. 6, to or from a user interface, such as the user interface 619 of FIG. 6, to a display associated with an energy absorption and heat storage system 602, to an external display, etc., and various combinations thereof. The information communicated may include, for example, information regarding a current state of equipment, such as information sensed at 804, information retrieved at 806, information regarding a calibration process or calibration device, information regarding the remaining energy capacity of the electrical load, such as information calculated or used in a calculation at 808, information regarding the appropriateness of using the electrical load to absorb energy associated with a calibration process, such as information determined or used in a determination at 810, evaluation information or information used in an evaluation at 812, etc., and various combinations thereof.

Examples of information regarding the current state of equipment include a temperature of a thermal mass (e.g., a temperature of a solid heat storage medium 250, 350, 450, 550 of FIGS. 2-5), a temperature of water (e.g., a temperature of a phase-change heat storage medium 140, 240 of FIGS. 1 and 2), a mass or fill level of water in a reservoir, an existing amount of heat storage capacity of an electrical load used or available. Information may be received from a calibrator such as a calibration device 692 of FIG. 6, an electrical vehicle charging station such as an electric vehicle charging station 690 of FIG. 6, a remote or cloud server 696 of FIG. 6, or various combinations thereof. For example, the maximum deliverable amperage and minimum measurable amount of power may be received form a calibrator or vehicle charging station or a cloud server.

The evaluation information may include an indication of whether an electrical load has enough available energy sinking capacity to absorb the amount of electrical energy associated with a calibration process.

Information regarding a remedy for any deficiencies may be provided, such as an indication to fill a water reservoir to a particular level, information indicating when sufficient heat will have been dissipated to permit use of the device, information regarding another electrical load that may be employed instead or in addition to the electrical load being evaluated, etc., and various combinations thereof. Additional information may be provided, such as a total number of heat cycles to which a load has been subjected, a total amount of energy absorbed or dissipated, measurements of added water, etc. Flags or counters of such additional information may be communicated or employed, for example, to schedule maintenance or service. Indications of changes in the performance of the load, such as information generated at 812, may be communicated. The communications may include signals, visual or audio indicators, alarms, etc.

The method 800 proceeds from 814 to 816, where the method 800 may stop, may provide information, such as the communicated information discussed above, to one or more calling processes or applications, may perform other operations, such as initiating a maintenance procedure, etc. Embodiments of the method 800 of FIG. 8 may contain additional acts not shown in FIG. 8, may not contain all of the acts shown in FIG. 8, may perform acts shown in FIG. 8 in various orders, may combine acts, may split acts into separate acts, and may be otherwise modified in various respects. For example, FIG. 8 may be modified to perform act 814 in parallel with acts 804, 806, 808, 810 and 812 in some embodiments, for example, to update communicated information as data is sensed at 804, retrieved at 806, calculated at 808, determined at 810 and evaluated and updated at 812.

FIG. 9 illustrates an embodiment of a method 900 of calculating a remaining energy capacity of an electrical load when water is employed as a phase-change heat storage medium, and vaporization is employed to dissipate heat stored in the water and will be described for convenience with reference to the system 100 of FIG. 1 when water is employed as the phase-change heat storage medium. The method 900 of FIG. 9 may be employed by the method 800 at act 808. The method 900 may be performed, for example, using or under the control of an energy capacity estimator, such as one or more of the energy capacity estimators 618, 618′, 618″, 618′″ of FIG. 6. The method 900 starts at 902, for example, in response to a request from a user interface 619 or a calibration device 692 for an indication of a current energy absorption capability of an electrical load, such as the system 100 of FIG. 1. The method 900 proceeds from 902 to 904.

At 904, the method 900 determines the temperature change required to boil water. This may be determined, for example, by subtracting a current temperature of the water from a retrieved or determined boiling temperature of water at a current pressure. The method 900 proceeds from 904 to 906.

At 906, the method 900 determines the mass of the water available, such as a mass of water in the reservoirs of the system 100 of FIG. 1. This may be performed using sensed information regarding water levels in the reservoirs and converting the sensed water levels to mass using conversion information, as described above with reference to act 708 of method 700. The method 900 proceeds from 906 to 908.

At 908, the method 900 calculates the amount of energy needed to effect the temperature change determined at 904 in the mass of water determined at 906. This may be done, for example, by multiplying the temperature change determined at 904 by a heat capacity of the mass of water determined at 906. The heat capacity of the mass of water may be determined using the mass of water determined at 906 and heat capacity information. The heat capacity information may be determined based on sensed, retrieved, or stored information in a known manner. The method 900 proceeds from 908 to 910.

At 910, the method 900 calculates the amount of energy needed to boil the mass of water determined at 906. This may be done, for example, by multiplying a heat of vaporization by the mass of water determined at 906. The heat of vaporization may be determined based on sensed, retrieved, or stored information in a known manner. The method 900 proceeds from 910 to 912.

At 912, the method 900 determines a total available energy absorption capacity of the electrical load, such as the system 100 of FIG. 1. This may be done, for example, by adding the amount of energy to effect the temperature change determined at 908 to the amount of energy to boil the water determined at 910.

The method 900 proceeds from 912 to 914, where the method 900 may stop, may provide the total available energy absorption capacity determined at 912 to one or more calling processes or applications, may perform other operations, such as initiating a maintenance procedure, etc. Embodiments of the method 900 of FIG. 9 may contain additional acts not shown in FIG. 9, may not contain all of the acts shown in FIG. 9, may perform acts shown in FIG. 9 in various orders, may combine acts, may split acts into separate acts, and may be otherwise modified in various respects. For example, FIG. 9 may be modified to consider safety factors or performance characteristics. For example, act 910 may be modified to reserve a portion of the water as a safety buffer (e.g., to subtract 10% from the determined mass at act 906 when calculating the energy at 910). In another example, characterization factors may be employed in acts 906, 908, 910 and 912 to account for differences in heat transfer or storage properties, such as differences indicated by stored historical performance data.

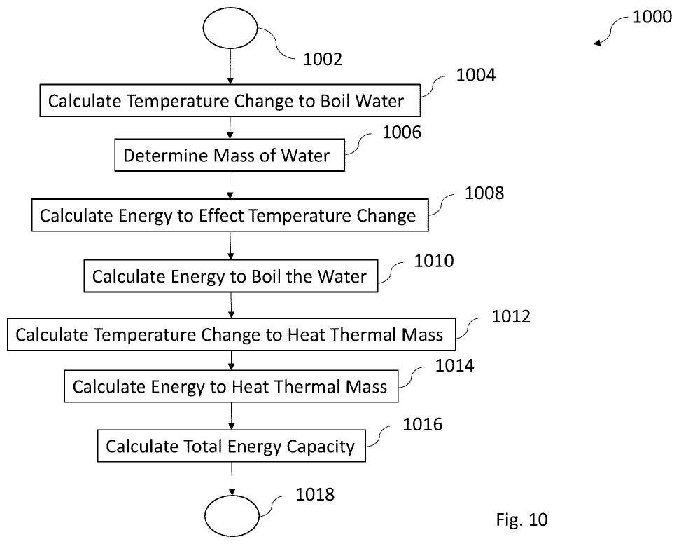

FIG. 10 illustrates an embodiment of a method 1000 of calculating a remaining energy capacity of an electrical load when a solid mass is employed as a heat storage medium in combination with the use of water as a phase-change heat storage medium, and vaporization is employed to dissipate heat stored in the water, and will be described for convenience with reference to the system 200 of FIG. 2. The method 1000 of FIG. 10 may be employed by the method 800 at act 808. The method 1000 may be performed, for example, using or under the control of an energy capacity estimator, such as one or more of the energy capacity estimators 618, 618′, 618″, 618′″ of FIG. 6.

The method 1000 starts at 1002, for example, in response to a request from a user interface 619 or a calibration device 692 for an indication of a current energy absorption capability of an electrical load, such as the system 200 of FIG. 2. The method 1000 proceeds from 1002 to 1004.

At 1004, the method 1000 determines the temperature change required to boil water. This may be determined, for example, as discussed above with reference to act 904 of FIG. 9. The method 1000 proceeds from 1004 to 1006.

At 1006, the method 1000 determines the mass of the water available, such as a mass of water in the reservoirs of the system 200 of FIG. 2. This may be determined, for example, as discussed above with reference to act 906 of FIG. 9. The method 1000 proceeds from 1006 to 1008.

At 1008, the method 1000 calculates the amount of energy needed to effect the temperature change determined at 1004 in the mass of water determined at 1006. This may be done, for example, as discussed above with reference to act 908 of FIG. 9. The method 1000 proceeds from 1008 to 1010.

At 1010, the method 1000 calculates the amount of energy needed to boil the mass of water determined at 1006. This may be done, for example, as discussed above with reference to act 910 of FIG. 9. The method 1000 proceeds from 1010 to 1012.

At 1012, the method 1000 determines or calculates the temperature change to heat the thermal mass. This may be determined, for example, by subtracting a current temperature of the thermal mass from a retrieved or determined maximum temperature of the thermal mass, e.g., a threshold maximum temperature set in accordance with design or safety considerations. The method 1000 proceeds from 1012 to 1014.

At 1014, the method 1000 determines or calculates an amount of energy to heat the thermal mass to the threshold maximum temperature. This may be done, for example, by multiplying the temperature change determined at 1012 by a heat capacity of the thermal mass. The heat capacity of the mass of water may be determined using a retrieved or stored mass of the thermal mass and heat capacity information for the thermal mass. The heat capacity information may be determined based on sensed, retrieved, or stored information, such as heat capacity information associated with the medium of the thermal mass (e.g., heat capacity information associated with alumina when alumina is employed as the thermal mass) in a known manner. The method 1000 proceeds from 1014 to 1016.

At 1016, the method 1000 determines a total available energy absorption capacity of the electrical load, such as the system 200 of FIG. 2. This may be done, for example, by adding the amount of energy to effect the temperature change determined at 1008, the amount of energy to boil the water determined at 1010, and the amount of energy to heat the thermal mass determined at 1014.

The method 1000 proceeds from 1016 to 1018, where the method 1000 may stop, may provide the total available energy absorption capacity determined at 1016 to one or more calling processes or applications, may perform other operations, such as initiating a maintenance procedure, etc. Embodiments of the method 1000 of FIG. 10 may contain additional acts not shown in FIG. 10, may not contain all of the acts shown in FIG. 10, may perform acts shown in FIG. 10 in various orders, may combine acts, may split acts into separate acts, and may be otherwise modified in various respects. For example, as discussed above with reference to FIG. 9, the method 1000 of FIG. 10 may be modified to consider safety factors or performance characteristics. For example, act 1010 may be modified to reserve a portion of the water as a safety buffer (e.g., to subtract a buffer amount (e.g. 10%) from the determined mass at act 1006 when calculating the energy at 1010). In another example, the threshold maximum temperature of the thermal mass employed at 1012 may be set below (e.g., 20% below) a design maximum temperature to provide a safety buffer. As discussed above with reference to FIG. 9, characterization factors may be employed in acts 1006, 1008, 1010, 1012, 1014 and 1016, to account for differences in heat transfer or storage properties, such as differences indicated by stored historical performance data.

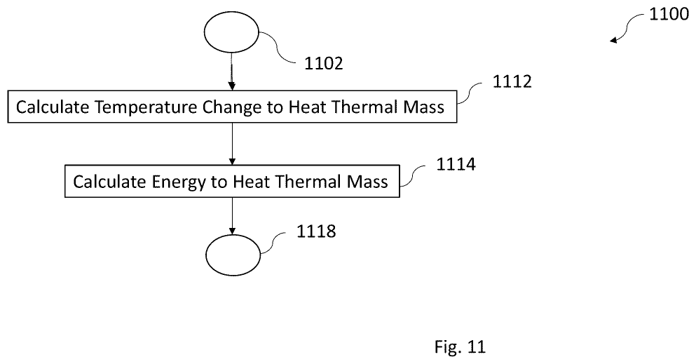

FIG. 11 illustrates an embodiment of a method 1100 of calculating a remaining energy capacity of an electrical load when a solid mass is employed as a heat storage medium, and will be described for convenience with reference to the system 300 of FIG. 3. The method 1100 of FIG. 11 may be employed by the method 800 at act 808. The method 1100 may be performed, for example, using or under the control of an energy capacity estimator, such as one or more of the energy capacity estimators 618, 618′, 618″, 618′″ of FIG. 6.

The method 1100 starts at 1102, for example, in response to a request from a user interface 619 or a calibration device 692 for an indication of a current energy absorption capability of an electrical load, such as the system 300 of FIG. 3, the system 400 of FIG. 4, or the system 500 of FIG. 5. The method 1100 proceeds from 1102 to 1112.

At 1112, the method 1100 determines or calculates the temperature change to heat the thermal mass. This may be determined, for example, by subtracting a current temperature of the thermal mass from a retrieved or determined maximum temperature of the thermal mass, e.g., a threshold maximum temperature set in accordance with design or safety considerations. The method 1100 proceeds from 1112 to 1114.

At 1114, the method 1100 determines or calculates an amount of energy to heat the thermal mass to the threshold maximum temperature. This may be done, for example, by multiplying the temperature change determined at 1112 by a heat capacity of the thermal mass. The heat capacity of the mass of water may be determined using a retrieved or stored mass of the thermal mass and heat capacity information for the thermal mass. The heat capacity information may be determined based on sensed, retrieved, or stored information, such as heat capacity information associated with the medium of the thermal mass (e.g., heat capacity information associated with alumina when alumina is employed as the thermal mass) in a known manner. The method 1100 proceeds from 1114 to 1118.

At 1118, the method 1100 may stop, may provide the available energy absorption capacity determined at 1114 to one or more calling processes or applications, may perform other operations, such as initiating a maintenance procedure, etc. Embodiments of the method 1100 of FIG. 11 may contain additional acts not shown in FIG. 11, may not contain all of the acts shown in FIG. 11, may perform acts shown in FIG. 11 in various orders, may combine acts, may split acts into separate acts, and may be otherwise modified in various respects. For example, as discussed above with reference to FIGS. 9 and 10, the method 1100 of FIG. 11 may be modified to consider safety factors or performance characteristics. For example, the threshold maximum temperature of the thermal mass employed at 1112 may be set below (e.g., 20% below) a design maximum temperature to provide a safety buffer. As discussed above with reference to FIGS. 9 and 10, characterization factors may be employed in acts 1112, and 1114, to account for differences in heat transfer or storage properties, such as differences indicated by stored historical performance data.

FIG. 12 illustrates an embodiment of a method of evaluating the performance of an electrical load during the absorption of electrical energy, and will be described for convenience with reference to the system 200 of FIG. 2 when water is used as a phase-change heat storage medium 240 and alumina is used as a solid heat storage mass or medium 250. The method 1200 of FIG. 12 may be employed by the method 800 at act 812. The method 1200 may be performed, for example, using or under the control of an energy capacity estimator, such as one or more of the energy capacity estimators 618, 618′, 618″, 618′″ of FIG. 6.

The method 1200 starts at 1202, for example, in response to a request from a user interface 619 or a calibration device 692 for an indication of a performance of a load during an energy absorption process, such as the performance of the system 200 of FIG. 2 during or after an energy absorption process. The method 1200 proceeds from 1202 to 1204.

At 1204, the method 1200 determines a change in temperature of water corresponding to delivery of a determined amount of energy to the energy absorption and heat storage system 200. This may be determined, for example, using sensed temperature values and measured or retrieved indications of an amount of energy delivered. The method 1200 proceeds from 1204 to 1206.

At 1206, the method 1200 determines a change in the amount of water remaining in a reservoir corresponding to delivery of a determined amount of energy to the energy absorption and heat storage system 200. This may be determined, for example, using sensed water levels in the reservoirs 222, 224, and measured or retrieved indications of an amount of energy delivered. The method 1200 proceeds from 1206 to 1208.

At 1208, the method 1200 determines a change in temperature of the alumina mass 250 corresponding to delivery of a determined amount of energy to the energy absorption and heat storage system 200. This may be determined, for example, using sensed temperature values and measured or retrieved indications of an amount of energy delivered. The method 1200 proceeds from 1208 to 1210. It is noted that different, or the same, determined amounts of energy may be employed in acts 1204, 1206 and 1208. For example, water temperature measurements may be taken at a different frequency than the sensing of water levels.

At 1210, the method 1200 characterizes one or more changes in the energy state of the system 200 corresponding to delivery of a determined amount of energy based on the changes in temperature and water levels determined for determined amounts of delivered energy. For example, a combined indication of a change in energy state may be determined, multiple indications of changes in multiple energy states may be determined, and various combinations thereof. The method proceeds from 1210 to 1212.

At 1212, the method compares the changes determined at acts 1204, 1206, and 1208, and the characterizations of act 1210 to historical indications of changes in temperature, water level and energy state for determined amounts of delivered energy. This information may be used to detect degradations in performance, to adjust calculations of remaining energy capacity at act 808 in the method 800 of FIG. 8, to determine the appropriateness of a load for an intended use at act 810 of the method 800 of FIG. 8 and may be communicated in act 814 of the method 800 of FIG. 8. The method 1200 proceeds from 1212 to 1214, where the method 1200 may stop, may provide the determined changes and characterizations to one or more calling processes or applications, may perform other operations, such as initiating a maintenance procedure or setting an alert signal, etc. Embodiments of the method 1200 of FIG. 12 may contain additional acts not shown in FIG. 12, may not contain all of the acts shown in FIG. 12, may perform acts shown in FIG. 12 in various orders, may combine acts, may split acts into separate acts, and may be otherwise modified in various respects. For example, when the method 1200 is employed with embodiments of the systems 300, 400 and 500 of FIGS. 3 through 5, acts 1204 and 1206 may be omitted. In another example, the determined changes and characterizations may be compared to safety thresholds, so that corrective action may be initiated, such as suspending a current calibration process if a measured temperature is rising to fast.

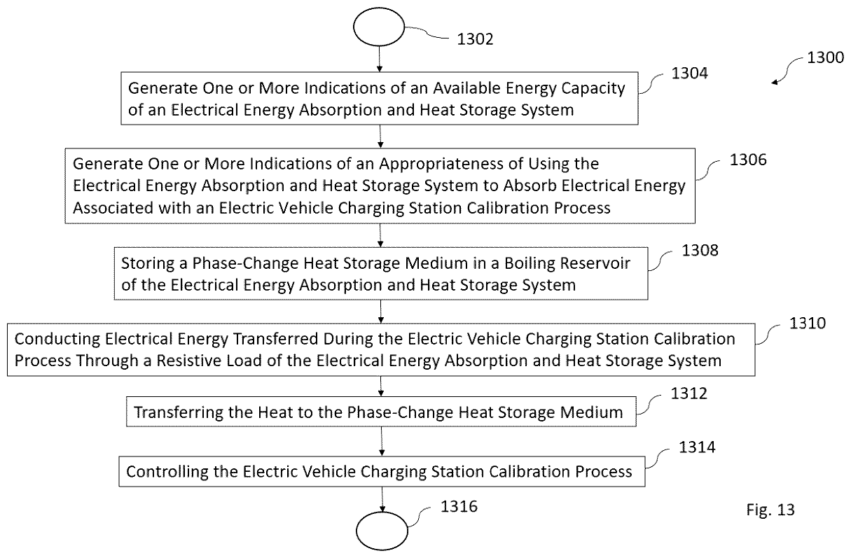

FIG. 13 illustrates an embodiment of a method of absorbing electrical energy transferred during a calibration process of an electric vehicle charging station, and will be described for convenience with reference to the system 100 of FIG. 1, the system 200 of FIG. 2, and the system 600 of FIG. 6. The method 1300 may be performed, for example, using or under the control of an energy capacity estimator, such as one or more of the energy capacity estimators 618, 618′, 618″, 618′″ of FIG. 6.

The method 1300 starts at 1302, for example, in response to a request from a user interface 619 or a calibration device 692 to initiate a calibration process. The method proceeds from 1302 to 1304.

At 1304, the method 1300 optionally generates one or more indications of an available energy capacity of an electrical energy absorption and heat storage system to absorb electrical energy associated with an electric vehicle charging station calibration process. This may be done, for example, as discussed above in the description of FIG. 11. The method 1300 proceeds from 1304 to 1306.

At 1306, the method 1300 optionally generates one or more indications of an appropriateness of using an electrical energy absorption and heat storage system to absorb electrical energy associated with an electric vehicle charging station calibration process. This may be done, for example, as discussed above in the description of FIG. 8. The method 1300 proceeds from 1306 to 1308.

At 1308, the method 1300 stores a phase-change heat storage medium in a boiling reservoir of the electrical energy absorption and heat storage system. For example, water may be stored in the boiling reservoir 124 of FIG. 1, or the boiling reservoir 224 of FIG. 2. The method 1200 proceeds from 1204 to 1206.

At 1310, the method 1300 conducts electrical energy transferred during the electric vehicle charging station calibration process through a resistive load of the electrical energy absorption and heat storage system, converting the electrical energy into heat. This may be done, for example, by conducting the electrical energy through the resistive load 110 of FIG. 1, or the resistive load 210 of FIG. 2. The method 1300 proceeds from 1310 to 1312.

At 1312, the method 1300 transfers the heat generated at 1310 to the phase-change heat storage medium. For example, water stored in a reservoir (see reservoir 124 of FIG. 1 and reservoir 224 of FIG. 2) may absorb the heat generated by the resistive load, and dissipate the heat as steam, as discussed above in the description of FIGS. 1 and 2. The method 1300 proceeds from 1312 to 1314.

At 1314, the method 1300 optionally controls the electric vehicle charging station calibration process, for example, based on the indications generated at 1304 and 1306. The method proceeds from 1314 to 1316, where the method 1300 may stop, may provide the generated indications to one or more calling processes or applications, may perform other operations, such as initiating a maintenance procedure or setting an alert signal, etc.

Embodiments of the method 1300 of FIG. 13 may contain additional acts not shown in FIG. 13, may not contain all of the acts shown in FIG. 13, may perform acts shown in FIG. 13 in various orders, may combine acts, may split acts into separate acts, and may be otherwise modified in various respects. For example, act 1314 may be performed in parallel with acts 1310 and 1312 in some embodiments. In another example, if the generated indications of the appropriateness of using the electrical energy absorption and heat storage system to absorb the electrical energy associated with the electric vehicle charging station calibration process indicate it is not appropriate to use the electrical energy absorption and heat storage system, act 1314 may control the calibration process so as to omit acts 1310 and 1312 or block the calibration process in some embodiments.

In light of the foregoing description, the following non-exclusive list of examples illustrates particular implementations of systems and methods that are contemplated by the present disclosure.

Example 1: An electrical energy absorption and heat storage system to absorb electrical energy transferred during a calibration process of an electric vehicle charging station, comprising a resistive load, which, in operation, receives the electrical energy and converts the electrical energy into heat; and a boiling reservoir, which, in operation, contains a phase-change heat storage medium, wherein, in operation, heat generated by the resistive load is transferred to the phase-change heat storage medium.

Example 2: Example 1, comprising a storage reservoir coupled to the boiling reservoir.

Example 3: Any of Examples 1 or 2, wherein the phase-change heat storage medium, in a first state, comprises water.

Example 4: Any of Examples 1-3, wherein the resistive load is positioned in the boiling reservoir.

Example 5: Any of Examples 3 or 4, comprising a vent, which, in operation, vents steam generated in the boiling reservoir when the water changes state.

Example 6: Any of Examples 3-5, comprising an inlet coupled to the storage reservoir, which, in operation, receives the water.

Example 7: Any of Examples 1-6, comprising a solid heat storage medium, wherein the resistive load is embedded in the solid heat storage medium, and in operation, heat generated by the resistive load is transferred to the solid heat storage medium, and selectively transferred from the solid heat storage medium to the phase-change heat storage medium.

Example 8: Any of Examples 1-7, comprising a storage reservoir, which, in operation, stores the phase-change heat storage medium; and a valve coupled between the storage reservoir and the boiling reservoir.

Example 9: Example 8, wherein the phase-change heat storage medium, in a first state, comprises water.

Example 10: Any of Examples 8 or 9, wherein, the storage reservoir has a translucent portion to provide a visible indication of a level of phase-change material in the storage reservoir; the boiling reservoir has a translucent portion to provide a visible indication of a level of phase-change material in the storage reservoir; or the storage reservoir has a translucent portion to provide a visible indication of a level of phase-change material in the storage reservoir and the boiling reservoir has a translucent portion to provide a visible indication of a level of phase-change material in the boiling reservoir.

Example 11: Any of Examples 8-10, wherein the solid heat storage medium has one or more surfaces having an oblique angle with respect to a surface of the boiling reservoir.

Example 12: Any of Examples 8-11, wherein the solid heat storage medium comprises a ceramic material.

Example 13: Example 12, wherein the solid heat storage medium comprises alumina. Example 14: Any of Examples 1-13, wherein the electrical energy absorption and heat storage system has a volume between 750 milliliters and forty liters, a weight between 10 and twenty pounds, or a volume between 750 milliliters and forty liters and a weight between 10 and twenty pounds.

Example 15: A system, comprises an electrical energy absorption and heat storage device to absorb electrical energy transferred during a calibration process of an electric vehicle charging station, and processing circuitry. The electrical energy absorption and heat storage device includes a resistive load, which, in operation, receives the electrical energy and converts the electrical energy into heat; and a boiling reservoir, which, in operation, contains a phase-change heat storage medium, wherein, in operation, heat generated by the resistive load is transferred to the phase-change heat storage medium. The processing circuitry, in operation, generates one or more indications of an available energy capacity of the electrical energy absorption and heat storage device based on sensed data and stored information; and generates one or more indications of an appropriateness of using the electric energy absorption and heat storage device to absorb electrical energy associated with an electric vehicle charging station calibration process based on the one or more indications of the available energy capacity of the electrical energy absorption and heat storage device.

Example 16: Example 15, comprising one or more sensors coupled to the electrical energy and heat storage device and to the processing circuitry, wherein the one or more sensors, in operation, generate the sensed data.

Example 17: Example 15, wherein the processing circuitry comprises calibration circuitry, which, in operation, controls the electric vehicle charging station calibration process based on the one or more indications of the appropriateness.

Example 18: A method of absorbing electrical energy transferred during a calibration process of an electric vehicle charging station comprises storing a phase-change heat storage medium in a boiling reservoir of an electrical energy absorption and heat storage system; conducting the electrical energy transferred during the calibration process through a resistive load of the electrical energy absorption and heat storage system, converting the electrical energy into heat; and transferring the heat to the phase-change heat storage medium stored in the boiling reservoir.

Example 19: Example 18, comprising generating one or more indications of an available energy capacity of the electrical energy absorption and heat storage system based on sensed data and stored information; and generating one or more indications of an appropriateness of using the electric energy absorption and heat storage system to absorb electrical energy associated with an electric vehicle charging station calibration process based on the one or more indications of the available energy capacity of the electrical energy absorption and heat storage system.

Example 20: Example 19, comprising controlling the electric vehicle charging station calibration process based on the one or more indications of the appropriateness.

Example 21: An electrical energy absorption and heat storage system to absorb electrical energy transferred during a calibration process of an electric vehicle charging station, comprising a resistive load, which, in operation, receives the electrical energy and converts the electrical energy into heat; a solid heat storage medium, wherein the resistive load is embedded in the solid heat storage medium, and in operation, heat generated by the resistive load is stored in the solid heat storage medium; and an insulated chamber containing the resistive load and the solid heat storage medium.

Example 22: Example 21, wherein the solid heat storage medium comprises a ceramic material.

Example 23: Example 21, wherein the solid heat storage medium comprises alumina.

Example 24: Example 21, comprising a heat sink, wherein, in operation, heat stored in the solid heat storage medium is selectively transferred to the heat sink.

Example 25: Example 21, comprising one or more ports in the insulated chamber, wherein the ports are sized and shaped to receive heat conductive elements.

Example 26: Example 25, comprising a heat sink having one or more heat conductive elements sized and shaped to be received by the one or more ports of the insulated chamber.

Example 27: Example 24, wherein the heat sink comprises one or more cooling fins; one or more heat radiation surfaces; one or more convention paths; or combinations thereof.

Example 28: Example 21, wherein, the solid heat storage medium comprises a conduction path, the insulated chamber comprises an inlet port and an output port, and in operation, the inlet port, the conduction path and the output port form a circulation path to selectively circulate cooling media through the solid heat storage medium.

Example 29: Example 28, comprising one or more couplings in the insulated chamber, wherein the couplings are sized and shaped to receive heat conductive elements; and a heat sink having one or more heat conductive elements sized and shaped to be received by the one or more couplings of the insulated chamber.

Example 30: Example 21, wherein, the insulated chamber comprises a removable or openable portion, and in operation, the removable or openable portion is selectively removed or opened to dissipate heat stored in the solid heat storage medium.

Example 31: Example 30, wherein, the solid heat storage medium comprises a conduction path, the insulated chamber comprises an inlet port and an output port, and in operation, the inlet port, the conduction path and the output port form a circulation path to selectively circulate cooling media through the solid heat storage medium.

Example 32: Example 30, wherein, the solid heat storage medium comprises a conduction path to selectively circulate cooling media through the solid heat storage medium.

Example 33: Example 30, comprising one or more couplings in the insulated chamber, wherein the couplings are sized and shaped to receive heat conductive elements; and a heat sink having one or more heat conductive elements sized and shaped to be received by the one or more couplings of the insulated chamber.

Example 34: Example 30, comprising a heat sink configured to couple to the solid heat storage medium.

Example 35: A method, comprising generating one or more indications of an available energy capacity of an electrical energy absorption and heat storage system based on sensed data and stored information; and generating one or more indications of an appropriateness of using the electric energy absorption and heat storage system to absorb electrical energy associated with an electric vehicle charging station calibration process based on the one or more indications of the available energy capacity of the electrical energy absorption and heat storage system.

Example 36: Example 35, wherein the generating one or more indications of the appropriateness of using the electrical energy absorption and heat storage system to absorb electrical energy associated with an electric vehicle charging station calibration process is based on characteristics of the electric vehicle charging station calibration process.

Example 37: Example 35, comprising: sensing the sensed data; and retrieving the stored information.

Example 38: Example 35, comprising: absorbing electrical energy associated with the calibration process based on the one or more generated indications of the appropriateness; and generating one or more indications of a performance of the electrical energy absorption and heat storage system in absorbing the electrical energy.

Example 39: Example 38, comprising updating the stored information based on the one or more generated indications of the performance of the electrical energy absorption and heat storage system in absorbing the electrical energy.

Example 40: Example 38, wherein the generating one or more indications of a performance comprises determining a change in temperature of water of the electrical energy absorption and heat storage system corresponding to absorption of a determined amount of electrical energy; determining a change in an amount of water of the electrical energy absorption and heat storage system corresponding to absorption of a determined amount of electrical energy; determining a change in temperature of a mass of the electrical energy absorption and heat storage system corresponding to absorption of a determined amount of electrical energy; or combinations thereof.

Example 41: Example 40, comprising generating an indication of a change in an energy state of the electrical energy absorption and heat storage system based on one or more of the generated indications of the performance.

Example 42: Example 35, wherein the generating one or more indications of an available energy capacity of an electrical energy absorption and heat storage system comprises determining a temperature change to boil water at a current pressure; determining a mass of water available in the electrical energy absorption and heat storage system; determining an amount of energy to effect the temperature change based on the determined temperature change and the determined mass of water; determining an amount of energy to boil the determined mass of water; and adding the determined amount of energy to effect the temperature change and the determined amount of energy to boil the water.

Example 43: Example 42, comprising determining a temperature change to heat a thermal mass of the electrical energy absorption and heat storage system to a threshold temperature; determining an amount of energy to heat the thermal mass to the threshold temperature; and adding the determined amount of energy to heat the thermal mass to the determined amount of energy to effect the temperature change and the determined amount of energy to boil the water.

Example 44: Example 35, comprising determining a temperature change to heat a thermal mass of the electrical energy absorption and heat storage system to a threshold temperature; and determining an amount of energy to heat the thermal mass to the threshold temperature.

Example 45: A non-transitory computer-readable medium having contents which cause a processing device to perform a method, the method comprising generating one or more indications of an available energy capacity of an electrical energy absorption and heat storage system based on sensed data and stored information; and generating one or more indications of an appropriateness of using the electric energy absorption and heat storage system to absorb electrical energy associated with an electric vehicle charging station calibration process based on the one or more indications of the available energy capacity of the electrical energy absorption and heat storage system.

Example 46: Example 45, wherein contents comprise instructions executed by the processing device.

Example 47: Example 45, wherein the method comprises generating one or more indications of a performance of the electrical energy absorption and heat storage system in absorbing the electrical energy.

Example 48: A device, comprising processing circuitry, which, in operation: generates one or more indications of an available energy capacity of an electrical energy absorption and heat storage system based on sensed data and stored information; and generates one or more indications of an appropriateness of using the electric energy absorption and heat storage system to absorb electrical energy associated with an electric vehicle charging station calibration process based on the one or more indications of the available energy capacity of the electrical energy absorption and heat storage system; and an interface coupled to the processing circuitry, wherein the interface, in operation, outputs the one or more generated indications.

Example 49: Example 48, comprising one or more sensors coupled to the interface and to the electrical energy absorption and heat storage system, wherein the one or more sensors, in operation, generate the sensed data.

Example 50: Example 48, comprising: a memory coupled to the processing circuitry, wherein the memory, in operation, stores the stored information.

Example 51: Example 48, wherein the processing circuitry comprises calibration circuitry, which, in operation, controls the electric vehicle charging station calibration process based on the one or more indications of the appropriateness.

Example 52: Example 48, wherein the processing circuitry, in operation: generates a request for stored information; transmits the request for stored information via the interface; and receives a response to the request via the interface.

Example 53: Example 48, wherein the processing circuitry, in operation: generates a request for sensed data; transmits the request for sensed data via the interface; and receives a response to the request for sensed data via the interface.

Example 54: Example 48, wherein the processing circuitry, in operation, generates the one or more indications of the appropriateness of using the electrical energy absorption and heat storage system to absorb electrical energy associated with an electric vehicle charging station calibration process based on characteristics of the electric vehicle charging station calibration process.

Example 55: Example 48, wherein the processing circuitry, in operation, generates one or more indications of a performance of the electrical energy absorption and heat storage system in absorbing electrical energy.

Example 56: Example 55, wherein the processing circuitry, in operation, updates the stored information based on the one or more generated indications of the performance of the electrical energy absorption and heat storage system in absorbing the electrical energy.

Example 57: An electrical energy absorption and heat storage system (100, 200, 602) to absorb electrical energy transferred during a calibration process of an electric vehicle charging station (690), comprises a resistive load (110, 210), which, in operation, receives the electrical energy and converts the electrical energy into heat; and a boiling reservoir (124, 224), which, in operation, contains a phase-change heat storage medium (140, 240), wherein, in operation, heat generated by the resistive load (110, 210) is transferred to the phase-change heat storage medium (140, 240).

Example 58: Example 57, comprising a storage reservoir (122, 222) coupled to the boiling reservoir (124, 224), wherein, optionally, the storage reservoir has a translucent portion to provide a visible indication of a level of phase-change material in the storage reservoir; the boiling reservoir has a translucent portion to provide a visible indication of a level of phase-change material in the storage reservoir; or the storage reservoir has a translucent portion to provide a visible indication of a level of phase-change material in the storage reservoir and the boiling reservoir has a translucent portion to provide a visible indication of a level of phase-change material in the boiling reservoir.

Example 59: Any of Examples 57 and 58, wherein the phase-change heat storage medium (140, 240), in a first state, comprises water.

Example 60: Any of Examples 57-59, wherein the resistive load (110, 210) is positioned in the boiling reservoir (124, 224).

Example 61: Any of Examples 57-60, comprising a vent (128, 228), which, in operation, vents steam generated in the boiling reservoir (124, 224) when the water changes state.

Example 62: Example 58, comprising an inlet (130, 230) coupled to the storage reservoir (122, 222), which, in operation, receives the water.

Example 63: Any of Examples 57-62, comprising: a solid heat storage medium (250), wherein the resistive load (210) is embedded in the solid heat storage medium (250), and in operation, heat generated by the resistive load (210) is transferred to the solid heat storage medium (250), and selectively transferred from the solid heat storage medium (250) to the phase-change heat storage medium (240).

Example 64: Example 63, comprising a storage reservoir (222), which, in operation, stores the phase-change heat storage medium (240); and a valve (227) coupled between the storage reservoir (222) and the boiling reservoir (224).

Example 65: Any of Examples 63 and 64, wherein the solid heat storage medium (250) has one or more surfaces having an oblique angle with respect to a surface of the boiling reservoir (224).

Example 66: Any of Examples 63-65, wherein the solid heat storage medium (250) comprises a ceramic material, and optionally, comprises alumina.

Example 67: Any of Examples 57-66, wherein the electrical energy absorption and heat storage system has a volume between 750 milliliters and forty liters, a weight between 10 and twenty pounds, or a volume between 750 milliliters and forty liters and a weight between 10 and twenty pounds.

Example 68: Any of Examples 57-67, comprising circuitry (619), which, in operation, generates one or more indications of an available energy capacity of the electrical energy absorption and heat storage system (100, 200, 602) based on sensed data and stored information; and generates one or more indications of an appropriateness of using the electric energy absorption and heat storage system (100, 200, 602) to absorb electrical energy associated with an electric vehicle charging station (690) calibration process based on the one or more indications of the available energy capacity of the electrical energy absorption and heat storage system (100, 200, 602); and optionally, one or more sensors coupled to circuitry, wherein the one or more sensors, in operation, generate the sensed data.

Example 69: A method (1300) of absorbing electrical energy transferred during a calibration process of an electric vehicle charging station (690), the method comprising storing (1308) a phase-change heat storage medium in a boiling reservoir (124, 224) of an electrical energy absorption and heat storage system (100, 200, 602); conducting (1310) the electrical energy transferred during the calibration process through a resistive load (110, 210) of the electrical energy absorption and heat storage system (100, 200, 602), converting the electrical energy into heat; and transferring (1312) the heat to the phase-change heat storage medium (140, 240) stored in the boiling reservoir (124, 224).

Example 70: Example 69, comprising generating (1304) one or more indications of an available energy capacity of the electrical energy absorption and heat storage system (100, 200, 602) based on sensed data and stored information; and generating (1306) one or more indications of an appropriateness of using the electric energy absorption and heat storage system (100, 200, 602) to absorb electrical energy associated with an electric vehicle charging station (690) calibration process based on the one or more indications of the available energy capacity of the electrical energy absorption and heat storage system.

Example 71: Any of Examples 69 and 70, comprising controlling (1314) the electric vehicle charging station calibration process based on the one or more indications of the appropriateness.

It should be understood that the various embodiments described above can be combined to provide yet further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. An electrical energy absorption and heat storage system to absorb electrical energy transferred during a calibration process of an electric vehicle charging station, comprising:
a resistive load, which, in operation, receives the electrical energy and converts the electrical energy into heat; and
a boiling reservoir, which, in operation, contains a phase-change heat storage medium, wherein, in operation, heat generated by the resistive load is transferred to the phase-change heat storage medium.

2. The electrical energy absorption and heat storage system of claim 1, comprising:
a storage reservoir coupled to the boiling reservoir.

3. The electrical energy absorption and heat storage system of claim 2, wherein the phase-change heat storage medium, in a first state, comprises water.

4. The electrical energy absorption and heat storage system of claim 3, wherein the resistive load is positioned in the boiling reservoir.

5. The electrical energy absorption and heat storage system of claim 4, comprising:
a vent, which, in operation, vents steam generated in the boiling reservoir when the water changes state.

6. The electrical energy absorption and heat storage system of claim 5, comprising:
an inlet coupled to the storage reservoir, which, in operation, receives the water.

7. The electrical energy absorption and heat storage system of claim 1, comprising:
a solid heat storage medium, wherein the resistive load is embedded in the solid heat storage medium, and in operation, heat generated by the resistive load is transferred to the solid heat storage medium, and selectively transferred from the solid heat storage medium to the phase-change heat storage medium.

8. The electrical energy absorption and heat storage system of claim 7, comprising:
a storage reservoir, which, in operation, stores the phase-change heat storage medium; and
a valve coupled between the storage reservoir and the boiling reservoir.

9. The electrical energy absorption and heat storage system of claim 8, wherein the phase-change heat storage medium, in a first state, comprises water.

10. The electrical energy absorption and heat storage system of claim 8, wherein:
the storage reservoir has a translucent portion to provide a visible indication of a level of phase-change material in the storage reservoir;
the boiling reservoir has a translucent portion to provide a visible indication of a level of phase-change material in the storage reservoir; or
the storage reservoir has a translucent portion to provide a visible indication of a level of phase-change material in the storage reservoir and the boiling reservoir has a translucent portion to provide a visible indication of a level of phase-change material in the boiling reservoir.

11. The electrical energy absorption and heat storage system of claim 8, wherein the solid heat storage medium has one or more surfaces having an oblique angle with respect to a surface of the boiling reservoir.

12. The electrical energy absorption and heat storage system of claim 8, wherein the solid heat storage medium comprises a ceramic material.

13. The electrical energy absorption and heat storage system of claim 12, wherein the solid heat storage medium comprises alumina.

14. The electrical energy absorption and heat storage system of claim 1, wherein,
the electrical energy absorption and heat storage system has a volume between 750 milliliters and forty liters,
the electrical energy absorption and heat storage system has a weight between 10 and twenty pounds, or
the electrical energy absorption and heat storage system has a volume between 750 milliliters and forty liters and a weight between 10 and twenty pounds.

15. A system, comprising:
an electrical energy absorption and heat storage device to absorb electrical energy transferred during a calibration process of an electric vehicle charging station, the electrical energy absorption and heat storage device including:
a resistive load, which, in operation, receives the electrical energy and converts the electrical energy into heat; and
a boiling reservoir, which, in operation, contains a phase-change heat storage medium, wherein, in operation, heat generated by the resistive load is transferred to the phase-change heat storage medium; and
processing circuitry, which, in operation:
generates one or more indications of an available energy capacity of the electrical energy absorption and heat storage device based on sensed data and stored information; and
generates one or more indications of an appropriateness of using the electric energy absorption and heat storage device to absorb electrical energy associated with an electric vehicle charging station calibration process based on the one or more indications of the available energy capacity of the electrical energy absorption and heat storage device.

16. The system of claim 15, comprising:
one or more sensors coupled to the electrical energy and heat storage device and to the processing circuitry, wherein the one or more sensors, in operation, generate the sensed data.

17. The system of claim 15, wherein the processing circuitry comprises calibration circuitry, which, in operation, controls the electric vehicle charging station calibration process based on the one or more indications of the appropriateness.

18. A method of absorbing electrical energy transferred during a calibration process of an electric vehicle charging station, the method comprising:
storing a phase-change heat storage medium in a boiling reservoir of an electrical energy absorption and heat storage system;
conducting the electrical energy transferred during the calibration process through a resistive load of the electrical energy absorption and heat storage system, converting the electrical energy into heat; and
transferring the heat to the phase-change heat storage medium stored in the boiling reservoir.

19. The method of claim 18, comprising:
generating one or more indications of an available energy capacity of the electrical energy absorption and heat storage system based on sensed data and stored information; and
generating one or more indications of an appropriateness of using the electric energy absorption and heat storage system to absorb electrical energy associated with an electric vehicle charging station calibration process based on the one or more indications of the available energy capacity of the electrical energy absorption and heat storage system.

20. The method of claim 19, comprising:
controlling the electric vehicle charging station calibration process based on the one or more indications of the appropriateness.
